(19) United States
(12) Patent Application Publication
(10) Pub. No.: US 2026/0198282 A1
(43) Pub. Date: Jul. 9, 2026

(54) INTEGRATED CIRCUIT DEVICE AND METHOD OF MANUFACTURING

(71) Applicant: TAIWAN SEMICONDUCTOR MANUFACTURING COMPANY, LTD., Hsinchu (TW)

(72) Inventors: Tao-Yi HUNG, Hsinchu (TW); Hsu-Ju CHEN, Hsinchu (TW); Wun-Jie LIN, Hsinchu (TW); Jam-Wem LEE, Hsinchu (TW); Kuo-Ji CHEN, Hsinchu (TW)

(21) Appl. No.: 19/174,088

(22) Filed: Apr. 9, 2025

Related U.S. Application Data
(60) Provisional application No. 63/741,580, filed on Jan. 3, 2025.

(51) Int. Cl. H01L 23/522; H01L 21/768; H01L 23/528

(52) U.S. Cl. CPC H10W 20/42; H10W 20/051; H10W 20/427; H10W 20/435

(57) ABSTRACT

An integrated circuit (IC) device includes a substrate having a front side and a back side opposite the front side along a thickness direction of the substrate, an active region over the front side of the substrate, a first doped region of a first dopant type over the active region, a second doped region of a second dopant type over the active region, and a back side via extending from the back side, through the substrate, to the front side, and in electrical contact with the first doped region. The second dopant type is different from the first dopant type. The first doped region and the second doped region configured as an anode and a cathode of a diode.

### RELATED APPLICATION(S)

This application claims the benefit of U.S. Provisional Application No. 63/741,580, filed Jan. 3, 2025, which is herein incorporated by reference in its entirety.

### BACKGROUND

An integrated circuit (“IC”) device includes one or more semiconductor devices represented in an IC layout diagram (also referred to as “layout diagram”, “IC layout”, or “layout”). A layout diagram is hierarchical and includes modules which carry out higher-level functions in accordance with the IC device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B are schematic cross-sectional views of various IC devices, in accordance with some embodiments.

FIGS. 2A, 2B, 2C, 2D, 2E, 2F, 2G, 2H, 2I are schematic views of layouts of circuit regions of IC devices, in accordance with some embodiments.

FIG. 3 is a schematic circuit diagram of a circuit of an IC device, in accordance with some embodiments.

FIGS. 4A, 4B, 4C, 4D are schematic cross-sectional views of circuit regions of IC devices,

FIGS. 5A, 5B, 5C, 5D are schematic views of layouts of circuit regions of IC devices, in accordance with some embodiments.

FIGS. 6A, 6B, 6C, 6D are schematic views of layouts of circuit regions of IC devices, in accordance with some embodiments.

FIGS. 7A, 7B are schematic views of layouts of circuit regions of IC devices, in accordance with some embodiments.

FIGS. 8A, 8B, 8C, 8D, 8E, 8F, 8G, 8H, 81, 8J, 8K, 8L, 8M are schematic cross-sectional views of a circuit region of an IC device at various stages in a manufacturing process, in accordance with some embodiments.

FIGS. 9A, 9B, 9C are flow charts of various methods, in accordance with some embodiments.

FIG. 10 is a block diagram of an electronic design automation (EDA) system in accordance with some embodiments.

FIG. 11 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Diodes are included in various circuits of IC devices, for example, for rectification, signal demodulation, overvoltage protection, circuit protection, electrostatic discharge (ESD) protection, voltage regulation, or the like. In some embodiments, an IC device comprises a diode on a front side of a substrate, and conductors on a back side of the substrate. The conductors are electrically coupled correspondingly to an anode and a cathode of the diode. In at least one embodiment, the IC device comprises a back side via which extends from the back side through the substrate to the front side to come into electrical contact with a lower portion or a back side portion of the anode or the cathode of the diode. As a result, it is possible in one or more embodiments to reduce a number of feed through vias (FTVs) that would otherwise be formed for electrical connections between the anode and the cathode of the diode on the front side with the corresponding conductors (e.g., input/output pads and/or power rails) on the back side. Such FTV reduction, in one or more embodiments, reduces parasitic capacitance introduced by metal routing during back-end-of-line (BEOL) fabrication, and/or reduces a chip area occupied by FTVs. In other words, improvements in one or more of performance, power, and area are achievable in at least one embodiment.

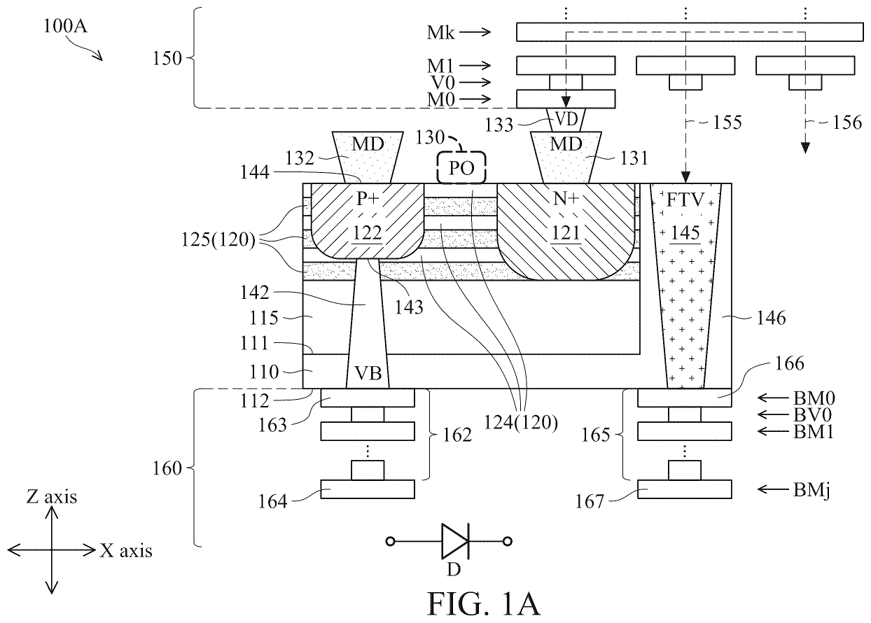

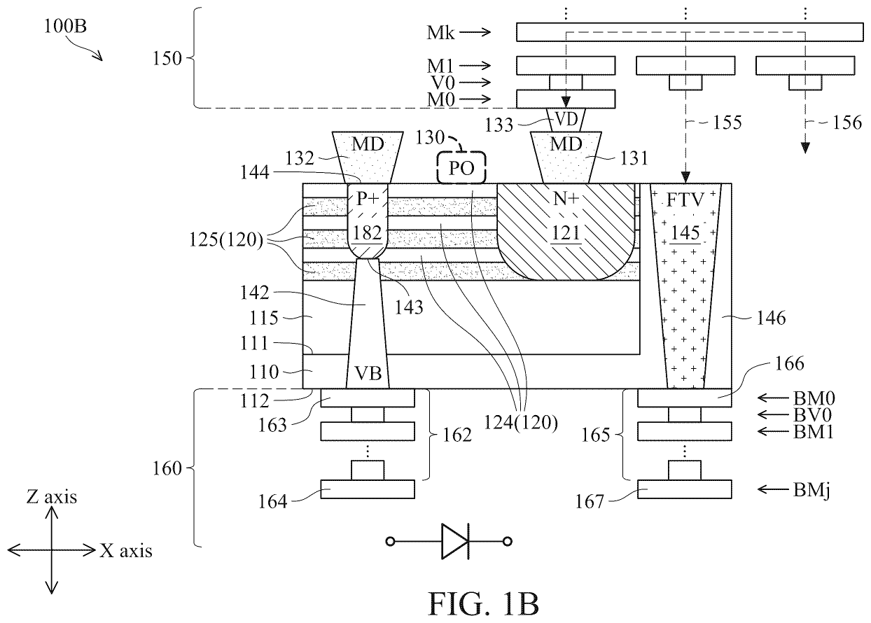

FIG. 1A is a schematic cross-sectional view of an IC device 100A, in accordance with some embodiments.

The IC device 100A comprises a substrate 110 having a front side 111, and a back side 112 opposite to the front side 111 in a thickness direction of the substrate 110. The thickness direction of the substrate 110 is also a thickness direction of the IC device 100A, and is designated as Z axis in the drawings. The front side 111 is sometimes referred to as “upper side” or “device side,” and the back side 112 is sometimes referred to as “lower side”. In some embodiments, the substrate 110 comprises an insulation layer. In the example configuration in FIG. 1A, the substrate 110 comprises a silicon nitride. Other non-conductive materials of the substrate 110, such as SiO, SiO₂, combinations thereof, or the like, are within the scopes of various embodiments. In some embodiments, the substrate 110 is a buried insulation layer of a silicon-on-insulator (SOI) substrate where the substrate 110 remains after a bulk of the SOI substrate has been removed, e.g., by wafer thinning, during the manufacturing processes. In one or more embodiments, the substrate 110 is deposited or regrown after the wafer thinning. Other manners and/or processes for forming the substrate 110 are within the scopes of various embodiments.

The IC device 100A further comprises, over the front side 111 of the substrate 110, a semiconductor layer 115 over which a diode D is formed. In the example configuration in FIG. 1A, the semiconductor layer 115 comprises Si. Other semiconductor materials of the semiconductor layer 115 are within the scopes of various embodiments. In at least one embodiment, the semiconductor layer 115 is omitted.

The IC device 100A further comprises an active region 120 over the semiconductor layer 115, i.e., over the front side 111 of the substrate 110. Active regions are sometimes referred to as oxide-definition (OD) regions, and are schematically illustrated in the drawings with the label “OD.” In at least one embodiment, the active region 120 is considered to comprise the semiconductor layer 115. In the example configuration in FIG. 1A, the active region 120 comprises a multilayer stack of layers 124, 125 alternatingly arranged in the Z axis. The layers 124 comprise a semiconductor material, such as Si, and are configured to form a plurality of nanosheets in the active region 120. The layers 125 comprise a sacrificial material, such as SiGe. In some embodiments, the sacrificial material of the layers 125 is replaced with a conductive material, e.g., a metal, in a gate replacement process to obtain a metal, all-around gate. In at least one embodiment, a gate replacement process is not performed in the described region of the IC device 100A, and the sacrificial material of the layers 125 remains in the IC device 100A upon completion of fabrication of the IC device 100A. The described materials of the layers 124, 125 are examples. Other materials for the layers 124, 125 are within the scopes of various embodiments. The described nanosheets in the active region 120 constitute an example. Other types of active region, such as active regions for metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanowire FETs, or the like, are within the scopes of various embodiments.

The IC device 100A further comprises an N-doped region 121 and a P-doped region 122 over the active region 120. N-doped regions are schematically illustrated in the drawings with the label “N+” and P-doped regions are schematically illustrated in the drawings with the label “P+”. The N-doped region 121 is an example of one of a first doped region of a first conductivity type and a second doped region of a second conductivity type different from the first conductivity type. The P-doped region 122 is an example of the other of the first doped region and the second doped region. The N-type of the N-doped region 121 is an example of one of the first conductivity type and the second conductivity type. The P-type of the P-doped region 122 is an example of the other of the first conductivity type and the second conductivity type. In some embodiments, the N-doped region 121 comprises N-type dopants, e.g., phosphorus, implanted into a region of the active region 120, and the P-doped region 122 comprises P-type dopants, e.g., boron, implanted into another region of the active region 120. The specifically described dopants are examples. Other N-type and/or P-type dopants are within the scopes of various embodiments. In the example configuration in FIG. 1A, the N-doped region 121 has a greater depth along the Z axis and a greater width along the X axis than the P-doped region 122. This is an example, and other configurations are within the scopes of various embodiments.

The N-doped region 121 is physically spaced from the P-doped region 122, along a X axis, by a undoped section (not numbered) of the active region 120. The undoped section of the active region 120 is sometimes referred to as an intrinsic semiconductor region, and configures, together with the N-doped region 121 and P-doped region 122, a P-I-N diode (or PIN diode) D. One of the N-doped region 121 and the P-doped region 122 configures an anode of the diode D, and the other of the N-doped region 121 and the P-doped region 122 configures a cathode of the diode D. In the example configuration in FIG. 1A, given the specific example materials described for one or more of the active region 120, the N-doped region 121 and P-doped region 122, the N-doped region 121 configures the cathode and the P-doped region 122 configures the anode of the diode D. Other configurations, e.g., where an N-doped region configures the anode and a P-doped region configures the cathode of a diode, are within the scopes of various embodiments.

In the example configuration in FIG. 1A, the IC device 100A further comprises a gate 130 over the undoped section of the active region 120 between the N-doped region 121 and the P-doped region 122. An example material of the gate 130 is polysilicon, which is sometimes referred to as “poly”. Gates or gate regions are schematically illustrated in the drawings with the label “PO.” In some embodiments, polysilicon in the gate 130 is replaced with a conductive material, e.g., a metal, in a gate replacement process to configure the gate 130 as a metal gate. In at least one embodiment, a gate replacement process is not performed in the described region of the IC device 100A, and polysilicon remains the material of the gate 130 in the IC device 100A upon completion of fabrication of the IC device 100A. The gate 130 is a dummy gate. In some embodiments, a dummy gate is not electrically coupled to another circuitry. The gate 130 and similar gates over other diodes (not shown) in the IC device 100A are formed, in some embodiments, for maintaining a predetermined or desirable pattern density. In some embodiments, the gate 130 and similar gates over other diodes (not shown) in the IC device 100A are omitted. In some embodiments, the IC device 100A further comprises a gate dielectric or gate oxide (not shown) between the undoped section of the active region 120 and the gate 130.

The IC device 100A further comprises a contact structure 131 and a contact structure 132 correspondingly over and in electrical contact with the N-doped region 121 and the P-doped region 122. Contact structures are sometimes referred to as metal-zero-over-oxide or metal-to-device structures, and are schematically illustrated in the drawings with the label “MD.” At least one of the contact structure 131 and the contact structure 132 configures an electrical connection from the corresponding N-doped region 121 and/or P-doped region 122 to other internal circuitry of the IC device 100A or to outside circuitry. The contact structure 131, gate 130 and contact structure 132 are arranged alternatively along the X axis. In some embodiments, a distance or spacing along the X axis between a center line of the gate 130 and a center line of the contact structure 131 is the same as a distance or spacing between the center line of the gate 130 and a center line of the contact structure 132. An example conductive material of the contact structures 131, 132 includes metal. Other configurations are within the scopes of various embodiments. The contact structure 131 is an example of one of a first contact structure and a second contact structure, and the contact structure 132 is an example of the other of the first contact structure and the second contact structure.

The IC device 100A further comprises one or more vias or via structures over and in electrical contact with the corresponding contact structures. A via structure over and in electrical contact with a contact structure is sometimes referred to as via-to-device, and is schematically illustrated in the drawings with the label “VD.” A via structure over and in electrical contact with a gate region is sometimes referred to as via-to-gate, and is schematically illustrated in the drawings with the label “VG.” In the example configuration in FIG. 1A, the gate 130 is a dummy gate and no VG via is formed over the gate 130. In some embodiments, a VG via is formed over the gate 130, but is not electrically coupled to further circuitry. A VD via 133 is over and in electrical contact with the contact structure 131. In some embodiments, a further VD via (not shown) is over and in electrical contact with the contact structure 132. An example material of VG vias and/or VD vias includes metal. Other configurations are within the scopes of various embodiments.

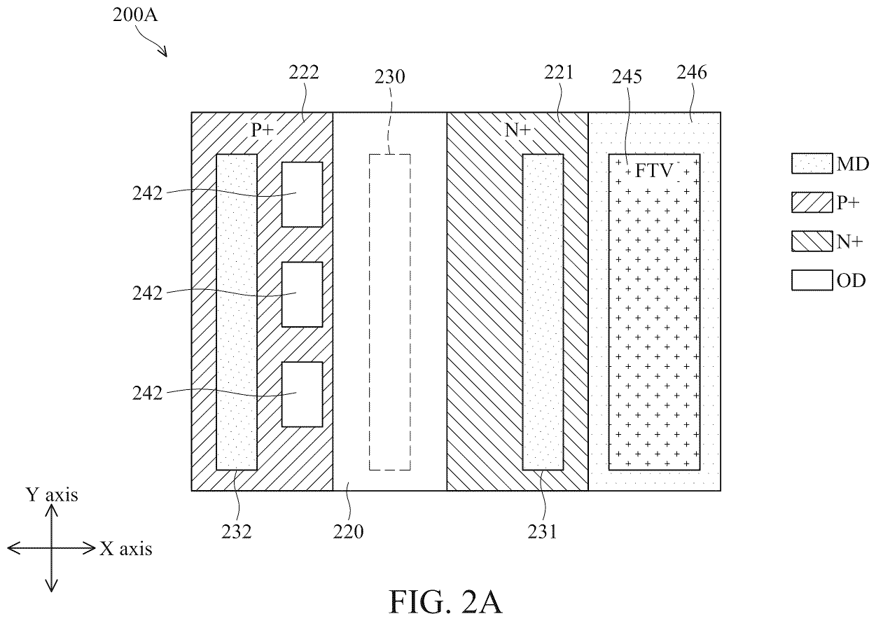

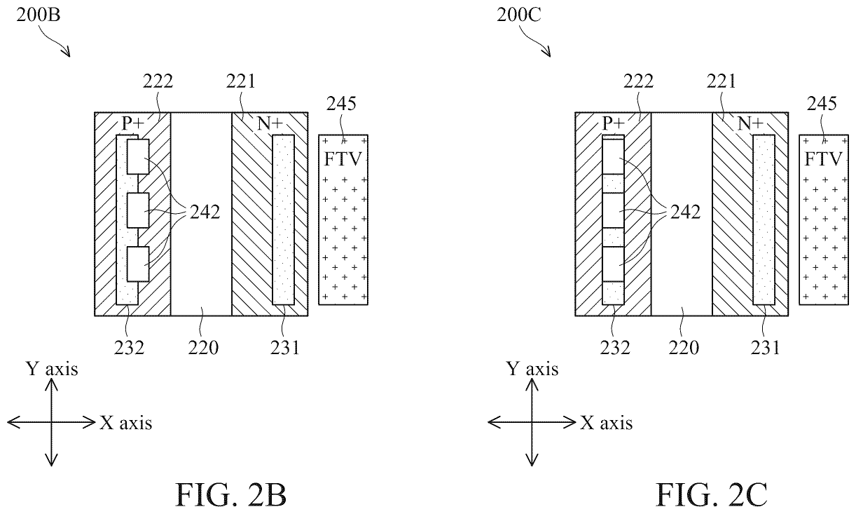

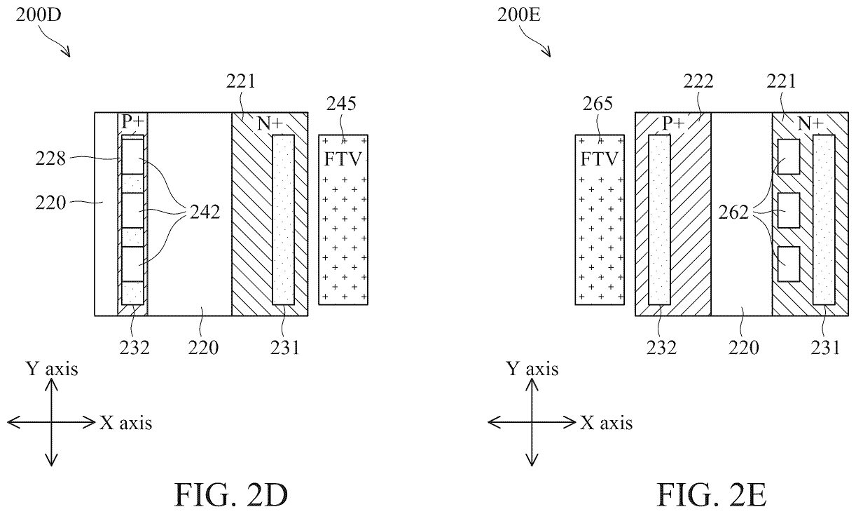

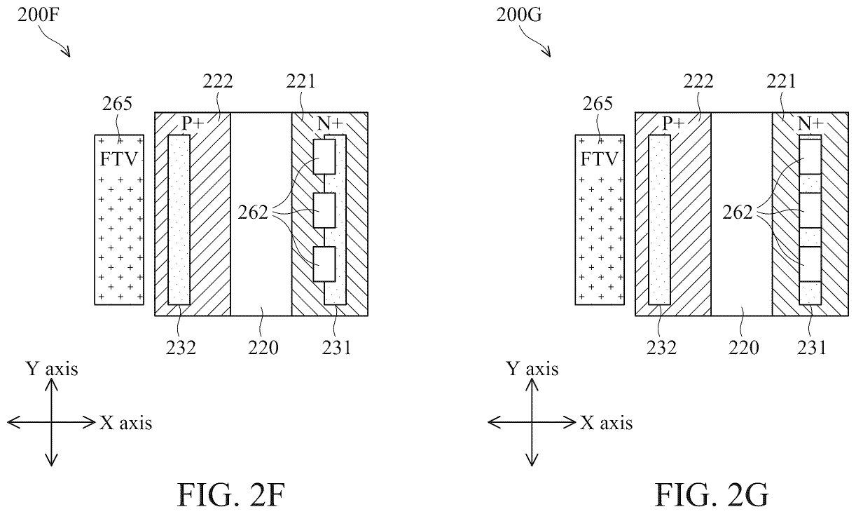

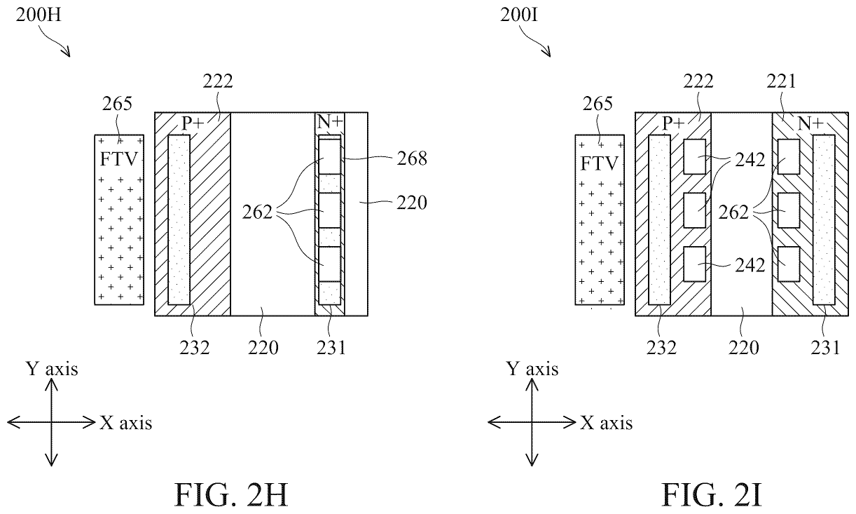

The IC device 100A further comprises a back side via 142 extending from the back side 112, through the substrate 110, to the front side 111 to come into electrical contact with the P-doped region 122. In the example configuration in FIG. 1A, the contact structure 132 and the back side via 142 are in direct contact with corresponding opposite surfaces 144, 143 of the P-doped region 122. Along the X axis, the back side via 142 has a width tapering from the back side 112 of the substrate 110 towards the P-doped region 122. Along the Z axis, the P-doped region 122 overlaps both the contact structure 132 and the back side via 142, and the contact structure 132 overlaps, at least partially, the back side via 142. Other configurations, e.g., where the contact structure 132 does not at all overlap the back side via 142 along the Z axis, or where the contact structure 132 overlaps an entirety of the back side via 142 along the Z axis, are within the scopes of various embodiments, for example, as described with respect to FIGS. 2A-2C. Back side vias are schematically illustrated in the drawings with the label “VB.” An example material of back side vias includes metal. Other configurations are within the scopes of various embodiments.

The IC device 100A is free of a further back side via similar to the back side via 142, extending from the back side 112, through the substrate 110, to the front side 111 to come into electrical contact with the N-doped region 121. In other words, in some embodiments, a single back side via is formed for each PIN diode having an N-doped region and a P-doped region, to electrically couple one of the N-doped region or the P-doped region of the PIN diode to the back side, without using a front side conductive structure over the N-doped region and P-doped region. The other of the N-doped region and the P-doped region is electrically coupled to the back side using a front side conductive structure over the N-doped region and P-doped region, as described herein. Other configurations, e.g., where both the N-doped region and a P-doped region of a PIN diode are electrically coupled to the back side by corresponding back side vias, are within the scopes of various embodiments.

The IC device 100A further comprises an FTV 145 extending, in the thickness direction (e.g., Z axis), along the N-doped region 121 and the P-doped region 122 on the front side 111, through the substrate 110, to the back side 112. In the example configuration in FIG. 1A, the FTV 145 is co-elevational with an entirety of each of the N-doped region 121 and the P-doped region 122. In other words, along the X axis, the FTV 145 overlaps the entirety of each of the N-doped region 121 and the P-doped region 122. The FTV 145 further extends, along the Z axis, beyond lowest portions of the N-doped region 121, P-doped region 122 to reach the back side 112. Along the Z axis, the FTV 145 has a greater length than the back side via 142. Along the X axis, the FTV 145 width tapering towards the back side 112 of the substrate 110. An example material of FTVs includes metal. FTV configurations other than that described with respect to FIG. 1A are within the scopes of various embodiments. In some embodiments, the FTV 145 is omitted, and the conductive structure 155 is also omitted at least partially.

The IC device 100A further comprises an isolation structure 146 in which the FTV 145 is embedded. An example material of the isolation structure 146 includes a silicon oxide (e.g., SiOx). Other materials are within the scopes of various embodiments. The isolation structure 146 is sometimes referred to as a shallow trench isolation (STI), and is configured to electrically isolate the active region 120 from an adjacent active region of another PIN diode in the IC device 100A. For example, the isolation structure 146 also exists on the opposite (left) side of the active region 120 in FIG. 1A, and is not entirely illustrated for simplicity. In some embodiments, in a plan view along the Z axis, the isolation structure 146 continuously extends to completely surround the active region 120. The described configuration in which the isolation structure 146 and the substrate 110 electrically isolate (except for the presence of the back side via 142 and FTV 145) the active region 120 from below and surrounding conductive features is sometimes referred to as a bulk-less configuration or bulk-less device. In an example, a bulk-less device is a semiconductor device formed or fabricated over an insulation layer. In a further example, a bulk-less device is a semiconductor device formed or fabricated over a bulk of a semiconductor substrate, and then the bulk of the semiconductor substrate is removed during further processing and replaced with an insulation layer. Other bulk-less device configurations and/or manufacturing processes are within the scopes of various embodiments. In some embodiments, the IC device 100A has a configuration other than a bulk-less device configuration.

The IC device 100A further comprises a redistribution structure 150 which is over the VD, VG vias. The redistribution structure 150 is over the front side 111 of the substrate 110 and is sometimes referred to as front side redistribution structure. The redistribution structure 150 comprises a plurality of metal layers and via layers sequentially and alternatingly arranged over the VD, VG vias. The redistribution structure 150 further comprises various interlayer dielectric (ILD) layers (not shown) in which the metal layers and via layers are embedded. The metal layers and via layers of the redistribution structure 150 are sometimes referred to as front side metal layers and front side via layers, and are configured to electrically couple various elements or circuits of the IC device 100A with each other and/or with external circuitry. In the redistribution structure 150, the lowermost metal layer immediately over and in electrical contact with the VD, VG vias is an M0 (metal-zero) layer, a next metal layer immediately over the M0 layer is an M1 layer, a next metal layer immediately over the M1 layer is an M2 layer, or the like. Conductive patterns in the M0 layer are referred to as M0 conductive patterns, conductive patterns in the M1 layer are referred to as M0 conductive patterns, or the like. A via layer Vn is arranged between and electrically couple the Mn layer and the Mn+1 layer, where n is an integer from zero and up. For example, a via-zero (V0) layer is the lowermost via layer which is arranged between and electrically couple the M0 layer and the M1 layer. Other via layers are V1, V2, or the like. Vias in the V0 layer are referred to as V0 vias, vias in the V1 layer are referred to as V1 vias, or the like. For simplicity, metal layers and via layers in the redistribution structure 150 are not fully illustrated in FIG. 1A.

The redistribution structure 150 comprises a conductive structure 155 electrically coupling the VD via 133, and hence the contact structure 131 and the N-doped region 121, to the FTV 145. The conductive structure 155 is sometimes referred to as a front side conductive structure. The conductive structure 155 comprises one or more conductive patterns (or conductors) in one or more metal layers and/or one or more vias in one or more via layers of the redistribution structure 150 electrically coupled together to form an electrical connection between a top surface of the VD via 133 and a top surface of the FTV 145. As a result, the N-doped region 121 is electrically coupled to the back side 112 of the substrate 110 through the conductive structure 155 and the FTV 145.

Alternatively or additionally, the redistribution structure 150 comprises a conductive structure 156 electrically coupling the VD via 133, and hence the contact structure 131 and the N-doped region 121, to a further conductive feature on a side (right side in FIG. 1A) opposite to the N-doped region 121 across the isolation structure 146. In at least one embodiment, the N-doped region 121 is electrically coupled to the back side 112 of the substrate 110 through the conductive structure 156 and the further conductive feature. Like the conductive structure 155, the conductive structure 156 comprises one or more conductive patterns in one or more metal layers and/or one or more vias in one or more via layers of the redistribution structure 150 electrically coupled together to form an electrical connection between a top surface of the VD via 133 and the further conductive feature. In some embodiments, the further conductive feature is a doped region over another active region, e.g., the conductive structure 156 electrically couples the N-doped region 121 to an anode or a cathode of another PIN diode, as described herein.

In some embodiments, the redistribution structure 150 comprises one of the conductive structure 155 and the conductive structure 156 but not the other. In at least one embodiment, the redistribution structure 150 comprises both the conductive structure 155 and the conductive structure 156. In the example configuration in FIG. 1A, a top or highest conductive pattern of the conductive structure 155 and the conductive structure 156 is in an Mk layer higher than the M1 layer. Other configurations are within the scopes of various embodiments. In an example, the highest conductive pattern of the conductive structure 155 and/or the conductive structure 156 is in the M1 layer, or the M0 layer.

The IC device 100A further comprises a redistribution structure 160 which is under the back side 112 of the substrate 110. The redistribution structure 160 is sometimes referred to as back side redistribution structure. The redistribution structure 160 comprises a plurality of metal layers and via layers sequentially and alternatingly arranged over the back side 112. The redistribution structure 160 further comprises various interlayer dielectric (ILD) layers (not shown) in which the metal layers and via layers are embedded. The metal layers and via layers of the redistribution structure 160 are sometimes referred to as back side metal layers and back side via layers, and are configured to electrically couple various elements or circuits of the IC device 100A with each other and/or with external circuitry. In the redistribution structure 160, the metal layer closest to the active region 120 and immediately under and in electrical contact with back side vias and FTVs is a BM0 layer, a next metal layer immediately under the BM0 layer is a BM1 layer, or the like. Conductive patterns in the BM0 layer are referred to as BM0 conductive patterns, conductive patterns in the BM1 layer are referred to as BM1 conductive patterns, or the like. A via layer BVm is arranged between and electrically couple the BMm layer and the BMm+1 layer, where m is an integer from zero and up. For example, a back side via-zero (BV0) layer is the via layer which closest to the active region 120 and is arranged between and electrically couple the BM0 layer and the BM1 layer. Other back side via layers are BV1, BV2, or the like. Vias in the BV0 layer are referred to as BV0 vias, vias in the BV1 layer are referred to as BV1 vias, or the like. For simplicity, metal layers and via layers in the redistribution structure 160 are not fully illustrated in FIG. 1A.

The redistribution structure 160 comprises a conductive structure 162 electrically coupling the back side via 142 to a conductor 164. The conductive structure 162 is sometimes referred to as a back side conductive structure. The conductive structure 162 comprises one or more conductive patterns in one or more metal layers and/or one or more vias in one or more via layers of the redistribution structure 160 electrically coupled together to form an electrical connection between a bottom surface of the back side via 142 and the conductor 164. As a result, the P-doped region 122 on the front side 111 is electrically coupled by the back side via 142 and the conductive structure 162 to the conductor 164 on the back side 112, without using a front side conductive feature in the redistribution structure 150. In some embodiments, a BM0 conductive pattern 163 of the conductive structure 162 is in direct contact with the bottom surface of the back side via 142.

Alternatively or additionally, the redistribution structure 160 comprises a conductive structure 165 electrically coupling the FTV 145 to a conductor 167. The conductive structure 165 is sometimes referred to as a back side conductive structure. The conductive structure 165 comprises one or more conductive patterns (or conductors) in one or more metal layers and/or one or more vias in one or more via layers of the redistribution structure 160 electrically coupled together to form an electrical connection between a bottom surface of the FTV 145 and the conductor 167. As a result, the N-doped region 121 on the front side 111 is electrically coupled by the conductive structure 155, the FTV 145 and the conductive structure 165 to the conductor 167 on the back side 112. In some embodiments, a BM0 conductive pattern 166 of the conductive structure 165 is in direct contact with the bottom surface of the FTV 145. In some embodiments where the FTV 145 is omitted, the conductive structure 165 is also omitted. In such embodiments, the N-doped region 121 is electrically coupled to the conductor 167, or a similar conductor on the back side 112, by the conductive structure 156 and further conductive features, as described herein. In the example configuration in FIG. 1A, the conductor 164 and the conductor 167 are in a BMj layer below the BM1 layer. Other configurations are within the scopes of various embodiments. In an example, the conductor 164 and/or the conductor 167 is/are in the BM1 layer, or the BM0 layer.

In some embodiments, each of the conductor 164 and the conductor 167 is configured to provide at least one of data, signal, voltage, power, ground, control, clock, or the like, to or from the diode D. In at least one embodiment, at least one of the conductor 164 or the conductor 167 is an input/output (I/O) pad configured to input signals to or receive signals from a core of functional circuitry of the IC device 100A. In one or more embodiments, at least one of the conductor 164 or the conductor 167 is configured to receive a positive power supply voltage or a reference voltage. For example, the positive power supply voltage is VDD and the reference voltage is the ground voltage, or VSS. In some embodiments, VDD is an example of one of a first power supply voltage and a second power supply voltage different from the first power supply voltage, and VSS is an example of the other of the first power supply voltage and the second power supply voltage.

In some embodiments, the conductor 164 or the conductor 167 is configured as a VDD power rail or a VSS power rail which is a part of a power delivery network in the redistribution structure 160. In at least one embodiment, a VDD power rail or a VSS power rail comprises an elongated conductive pattern in a metal layer, e.g., the BM0 layer or the BM1 layer, of the redistribution structure 160. The elongated conductive pattern, or power rail, extends continuously across multiple circuits, regions, e.g., across an array of multiple diodes, of the IC device 100A. In an example, the power delivery network in the redistribution structure 160 comprises multiple VDD power rails and multiple back side VSS power rails which are arranged alternatingly and which are electrically coupled, e.g., by corresponding FTVs similar to the FTV 145, to deliver power to functional circuitry on the front side 111 of the IC device 100A. The functional circuitry of the IC device 100A is electrically coupled to, and powered by, VDD and VSS provided from the back side 112. A back side power delivery network is sometimes referred to as a super power rail (SPR) structure.

In some embodiments, as described herein, an anode or a cathode of a PIN diode on a front side of a substrate is electrically coupled to a conductor on a back side of the substrate by a back side via. As a result, it is possible in one or more embodiments to omit an FTV and an associated front side conductive structure for electrically coupling such FTV to the anode or cathode of the PIN diode. For example, the P-doped region 122, which is the anode of the diode D, on the front side 111 of the substrate 110 is electrically coupled to the conductor 164 on the back side 112 of the IC device 100A by the back side via 142. As a result, it is possible to omit an FTV similar to the FTV 145 and an associated front side conductive structure similar to the conductive structure 155 which would otherwise required in accordance with other approaches for electrically coupling the P-doped region 122 to the back side 112.

The omission of an FTV and an associated front side conductive structure reduces parasitic capacitance on the front side, in one or more embodiments. In some embodiments, although a distance (along the X axis) between the back side via 142 and the FTV 145 is shorter compared to a distance between two FTVs in the other approaches, an increase in parasitic capacitance on the back side due to the reduced distance is smaller than the described reduction of parasitic capacitance on the front side. As a result, the overall parasitic capacitance is still advantageously reduced, in one or more embodiments. Such reduced overall parasitic capacitance leads to improvements in speed or performance, in one or more embodiments.

In some embodiments, the omission of an FTV that would otherwise be required in accordance with the other approaches reduces a chip area occupied by FTVs. As a result, it is possible in one or more embodiments to reduce the size of the IC device 100A and/or to free up the chip area of the IC device 100A for other circuitry. In at least one embodiment, the FTV 145 is also omitted, with further area improvements.

In some embodiments, the omission of an FTV related front side conductive structure that would otherwise be required in accordance with the other approaches not only reduces parasitic capacitance, but also simplifies a routing operation and/or frees up routing resources for other circuits. In at least one embodiment where the FTV 145 is omitted, the conductive structure 155 is also omitted, at least partially, with further improvements in and/or simplification of the routing operation.

FIG. 1B is a schematic cross-sectional view of an IC device 100B, in accordance with some embodiments. For simplicity, corresponding components in FIGS. 1A, 1B are designated by the same reference numerals.

The IC device 100B comprises a P-doped region 182 with a smaller width along the X axis than the P-doped region 122 in the IC device 100A. An example of a physical arrangement of the contact structure 132 and the back side via 142 with respect to the P-doped region 182 is as described with respect to FIG. 2D. One or more advantages described herein are achievable by the IC device 100B, in accordance with some embodiments.

FIGS. 2A, 2B, 2C, 2D, 2E, 2F, 2G, 2H, 2I are schematic views of layouts of circuit regions of corresponding IC devices 200A, 200B, 200C, 200D, 200E, 200F, 200G, 200H, 200I, in accordance with some embodiments. In at least one embodiment, the IC devices 200A, 200B, 200C correspond to the IC device 100A, and the IC device 200D corresponds to the IC device 100B. In some embodiments, the IC devices 200E, 200F, 200G, 200H are correspondingly similar to the IC devices 200A, 200B, 200C, 200D, a difference being that the IC devices 200E, 200F, 200G, 200H include back side vias under N-doped regions whereas the IC devices 200A, 200B, 200C, 200D include back side vias under P-doped regions. The IC device 200I comprises back side vias under both a P-doped region and an N-doped region. In some embodiments, multiple configurations described with respect to FIGS. 2A-2I are included in a single IC device. For simplicity, corresponding components in FIGS. 2A-2I are designated by the same reference numerals.

In FIG. 2A, the IC device 200A comprises an active region 220, an N-doped region 221, a P-doped region 222, a gate region 230, contact structures 231, 232, back side vias 242, an FTV 245, and an isolation structure 246. The N-doped region 221 and the P-doped region 222 are over the active region 220. In some embodiments, an entirety of each of the N-doped region 221 and the P-doped region 222 is completely within, or overlapped by, the active region 220. The N-doped region 221 is spaced from the P-doped region 222 along the X axis by a undoped section of the active region 220 over which the gate region 230 is arranged. The contact structures 231, 232, are correspondingly over the N-doped region 221 and the P-doped region 222. The gate region 230 and the contact structures 231, 232 are elongated along a Y axis transverse to the X axis. In at least one embodiment, the Y axis is perpendicular to the X axis. A distance or spacing along the X axis between a center line of the gate region 230 and a center line of the contact structure 231 is the same as a distance or spacing between the center line of the gate region 230 and a center line of the contact structure 232. In at least one embodiment, the gate region 230 is omitted.

The FTV 245 is completely within the isolation structure 246 which abuts a side of the active region 220. In some embodiments, the isolation structure 246 extends continuously to completely surround the active region 220 and abuts all sides of the active region 220. The size, shape and location of the FTV 245 in FIG. 2A are examples. Any other sizes and/or shapes and/or locations of the FTV 245 are within the scopes of various embodiments, provided that it is possible or feasible to route an electrical connection between the FTV 245 and the contact structure 231 where such electrical connection is required or desirable. In at least one embodiment, the FTV 245 is omitted. In some embodiments, the active region 220, the N-doped region 221, the P-doped region 222, the gate region 230, the contact structures 231, 232, each of the back side vias 242, the FTV 245, and the isolation structure 246 correspond to the active region 120, the N-doped region 121, the P-doped region 122, the gate 130, the contact structures 131, 132, the back side via 142, the FTV 145, and the isolation structure 146.

The back side vias 242 are arranged under the P-doped region 222, and are also arranged at an interval along the Y axis, i.e., along the contact structure 232. There are three back side vias 242 in the example configuration in FIG. 2A. Other numbers of back side vias under a doped region are within the scopes of various embodiments. For example, in at least one embodiment, the IC device 200A includes only one back side via 242 under the P-doped region 222. On a back side of a substrate (not shown) of the IC device 200A, the back side vias 242 are electrically coupled to a same conductor. The layout view in FIG. 2A corresponds to a plan view along a thickness direction of the substrate of the IC device 200A. In such a plan view, as shown in FIG. 2A, the contact structure 232 does not overlap the back side vias 242. Other arrangements are within the scopes of various embodiments, for example, as described with respect to FIGS. 2B, 2C.

In FIG. 2B, the IC device 200B differs from the IC device 200A in the relative arrangement of the contact structure 232 and the back side vias 242. Specifically, in the plan view in FIG. 2B, the contact structure 232 overlaps a portion, but not an entirety, of each of the back side vias 242.

In FIG. 2C, the IC device 200C differs from the IC devices 200A, 200B in the relative arrangement of the contact structure 232 and the back side vias 242. Specifically, in the plan view in FIG. 2C, the contact structure 232 overlaps an entirety of each of the back side vias 242. The various configurations described with respect to FIGS. 2A-2C demonstrate design flexibility in accordance with some embodiments where the doped region with one or more back side vias is relatively wide. An example embodiment where the doped region with one or more back side vias is relatively narrow is described with respect to FIG. 2D.

In FIG. 2D, the IC device 200D differs from the IC devices 200A, 200B, 200C in having a P-doped region 228 which has a narrower width along the X axis than the P-doped region 222. In some embodiments, the P-doped region 228 corresponds to the P-doped region 182 described with respect to FIG. 1B. Due to the narrow width of the P-doped region 228, the contact structure 232 overlaps an entirety of each of the back side vias 242. In some embodiments, where the contact structure 232 does not overlap an entirety of each of the back side vias 242, the contact structure 232 overlaps a substantial portion of each of the back side vias 242.

In FIGS. 2E-2H, the IC devices 200E-200H are correspondingly similar to the IC devices 200A-200D, a difference being that the IC devices 200E-200H include back side vias 262 under an N-doped region, whereas the back side vias 242 under the P-doped region 222 are omitted.

In FIG. 2E, the IC device 200E comprises an FTV 265 instead of the FTV 245 described with respect to FIGS. 2A-2D. Like the FTV 245, the FTV 265 is completely within an isolation structure (not shown). In some embodiments, the FTV 265 is embedded in the isolation structure 246 which extends continuously to completely surround the active region 220 and abuts all sides of the active region 220. The size, shape and location of the FTV 265 in FIG. 2E are examples. Any other sizes and/or shapes and/or locations of the FTV 265 are within the scopes of various embodiments, provided that it is possible or feasible to route an electrical connection between the FTV 265 and the contact structure 232 where such electrical connection is required or desirable. In some embodiments, an electrical connection or a corresponding front side conductive structure between the FTV 265 and the contact structure 232 is similar to that between the contact structure 131 and the FTV 145 as described with respect to FIG. 1A. In at least one embodiment, the FTV 265 and the front side conductive structure associated therewith are omitted.

The back side vias 262 are arranged under the N-doped region 221, and are also arranged at an interval along the Y axis, i.e., along the contact structure 231. There are three back side vias 262 in the example configuration in FIG. 2E. Other numbers of back side vias under a doped region are within the scopes of various embodiments. For example, in at least one embodiment, the IC device 200E includes only one back side via 262 under the N-doped region 221. On a back side of a substrate (not shown) of the IC device 200E, the back side vias 262 are electrically coupled to a same conductor. The layout view in FIG. 2E corresponds to a plan view along a thickness direction of the substrate of the IC device 200E. In such a plan view, as shown in FIG. 2E, the contact structure 231 does not overlap the back side vias 262. Other arrangements are within the scopes of various embodiments, for example, as described with respect to FIGS. 2F, 2G.

In FIG. 2F, the IC device 200F differs from the IC device 200E in the relative arrangement of the contact structure 231 and the back side vias 262. Specifically, in the plan view in FIG. 2F, the contact structure 231 overlaps a portion, but not an entirety, of each of the back side vias 262.

In FIG. 2G, the IC device 200G differs from the IC devices 200E, 200F in the relative arrangement of the contact structure 231 and the back side vias 262. Specifically, in the plan view in FIC. 2G, the contact structure 231 overlaps an entirety of each of the back side vias 262. The various configurations described with respect to FIGS. 2E-2G demonstrate design flexibility in accordance with some embodiments where the doped region with one or more back side vias is relatively wide. An example embodiment where the doped region with one or more back side vias is relatively narrow is described with respect to FIC. 2H.

In FIG. 2H, the IC device 200H differs from the IC devices 200E, 200F, 200G in having an N-doped region 268 which has a narrower width along the X axis than the N-doped region 221. Due to the narrow width of the N-doped region 268, the contact structure 231 overlaps an entirety of each of the back side vias 262. In some embodiments, where the contact structure 231 does not overlap an entirety of each of the back side vias 262, the contact structure 231 overlaps a substantial portion of each of the back side vias 262.

In FIG. 2I, the IC device 200I differs from the IC devices 200A-200H in having back side vias under both the N-doped region and the P-doped region. In contrast, in the IC devices 200A-200H, back side vias 242 are arranged under either the N-doped region or the P-doped region, not both. Specifically, in the IC device 200I, the back side vias 242 are arranged under the P-doped region 222 and the back side vias 262 are arranged under the N-doped region 221, in manners similar to those described with respect to FIGS. 2A, 2E. Other configurations described with respect to one or more of FIGS. 2B-2D, 2F-2H are applicable to the IC device 200I, in one or more embodiments. In the example configuration in FIG. 2E, because the N-doped region 221 and the P-doped region 222 are electrically coupled to the back side correspondingly by the back side vias 262 and the back side vias 242, there is no need for an FTV and both of the FTV 245 and the FTV 265 are omitted.

In some situations, the arrangement of back side vias under both an N-doped region and a P-doped region in the same active region leads to an increase in parasitic capacitance on the back side due to the close distance along the X axis between the back side vias, e.g., between the back side vias 242 and the back side vias 262. In some embodiments, despite such an increase in parasitic capacitance on the back side, an even greater reduction of parasitic capacitance on the front side is achievable, e.g., due to the omission of both the FTV 245 and the FTV 265 and the associated front side conductive structures. As a result, the overall parasitic capacitance is still advantageously reduced, in one or more embodiments.

The layout in each of FIGS. 2A-2I is a diode layout that represents a diode having an anode configured by the P-doped region and a cathode configured by the N-doped region. In some embodiments, the layout in at least one of FIGS. 2A-2I (with or without the corresponding FTV) is stored as a diode cell in a cell library on a non-transitory computer-readable medium. In at least one embodiment, a combination of multiple layouts in one or more of FIGS. 2A-2I (with or without the corresponding FTV) is stored as a further diode cell in the cell library. In some embodiments, one or more of the stored diode cells are read out from the cell library and placed, e.g., in a repeating pattern, in an automated placement and routing (APR) operation and/or by an APR tool (e.g., an EDA tool or system), to obtain an IC layout of an IC device to be manufactured. One or more advantages described herein are achievable by one or more of the IC devices 200A-200I, in accordance with some embodiments.

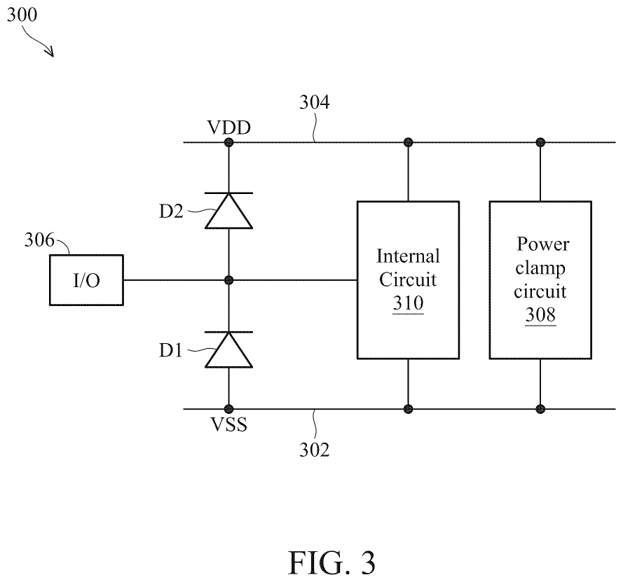

In some embodiments, the diode configurations described with respect to FIGS. 1A-1B and/or the diode layouts described with respect to FIGS. 2A-2I are applicable to any circuits and/or applications that include or use one or more diodes. A non-limiting example of such a circuit, in accordance with some embodiments, is described with respect to FIG. 3.

FIG. 3 is a schematic circuit diagram of a circuit of an IC device 300, in accordance with some embodiments. In some embodiments, the IC device 300 corresponds to one or more of the IC devices described with respect to FIGS. 1A-1B, 2A-2I.

The IC device 300 includes a VSS power rail 302, a VDD power rail 304, an input/output (I/O) terminal, or I/O pad, 306, diodes D1, D2, a power clamp circuit 308, and an internal circuit 310. In some embodiments, the VSS power rail 302, the VDD power rail 304 and the I/O pad 306 are on a back side of a substrate (not shown) of the IC device 300, whereas the diodes D1, D2, power clamp circuit 308 and internal circuit 310 are on the front side of the substrate.

The internal circuit 310 is electrically coupled between the VSS power rail 302 and the VDD power rail 304. Furthermore, the internal circuit 310 is connected through the I/O pad 306 in order to receive input and/or output signals that are external to the IC device 300. In some embodiments, the internal circuit 310 includes a PMOS driver (not shown), an NMOS driver (not shown), and a functional circuit (not shown), which are provided on the front side of the substrate of the IC device 300. The functional circuit is configured to perform a particular function or functions. For example, the functional circuit includes one or more of memory, combinational logic, sequential devices, sequential state components, digital processing circuits, radio frequency (RF) circuits, or the like. The PMOS driver and the NMOS driver are configured to convert signals of a lower voltage level of the functional circuit in the internal circuit 310 to corresponding signals of a higher voltage level at the I/O pad 306, or vice versa. In some embodiments, the PMOS driver and the NMOS driver are omitted.

To protect the internal circuit 310 from an ESD event (e.g., an excessive ESD voltage or ESD current), the diodes D1, D2 and the power clamp circuit 308 together form an ESD protection circuit. The diode D1, the diode D2, and the power clamp circuit 308 are configured to prevent the coupling of excessive electrostatic buildup from discharging into the internal circuit 310 and instead harmlessly discharge the electrostatic energy to the power rails 302, 304. Thus, the diode D1, the diode D2, and the power clamp circuit 308 are configured to prevent the internal circuit 310 from becoming damaged by bypassing positive or negative electrostatic current through a lower resistance path under various possible ESD events.

The diode DI is electrically coupled between the I/O pad 306 and the VSS power rail 302. In some embodiments, the diode D1 corresponds to the diode D described with respect to FIG. 1A, and comprises an anode (e.g., a P-doped region) on the front side electrically coupled to the VSS power rail 302 on the back side, and a cathode (e.g., an N-doped region) on the front side electrically coupled to the I/O pad 306 on the back side.

The diode D2 is electrically coupled between the I/O pad 306 and the VDD power rail 304. In some embodiments, the diode D2 corresponds to the diode D described with respect to FIG. 1A, and comprises an anode (e.g., a P-doped region) on the front side electrically coupled to the I/O pad 306 on the back side, and a cathode (e.g., an N-doped region) on the front side electrically coupled to the VDD power rail 304 on the back side.

The diode D1 is configured to discharge electrostatic current from the VSS power rail 302 toward the diode D2. The diode D1 is further configured to block electrostatic current from the I/O pad 306 toward the VSS power rail 302. The diode D2 is configured to block electrostatic current from the VDD power rail 304 toward the internal circuit 310 or the I/O pad 306. The diode D2 is further configured to discharge electrostatic current from the internal circuit 310, the I/O pad 306 or the diode D1, to the VDD power rail 304.

The power clamp circuit 308 is electrically coupled between the VDD power rail 304 and the VSS power rail 302, and is configured to provide a conductive path between the VDD power rail 304 and the VSS power rail 302 when an ESD event occurs, for example, on the VDD power rail 304. The described ESD protection circuit is an example. Other ESD protection circuit configurations are within the scopes of various embodiments.

In at least one embodiment, at least one of the anode or the cathode of at least one of the diodes D1, D2 is electrically coupled to the corresponding I/O pad 306, VDD power rail 304 or VSS power rail 302 on the back side by one or more back side vias as described with respect to FIGS. 1A-1B, 2A-2I. As a result, it is possible in one or more embodiments to achieve, in the IC device 300, one or more advantages described herein.

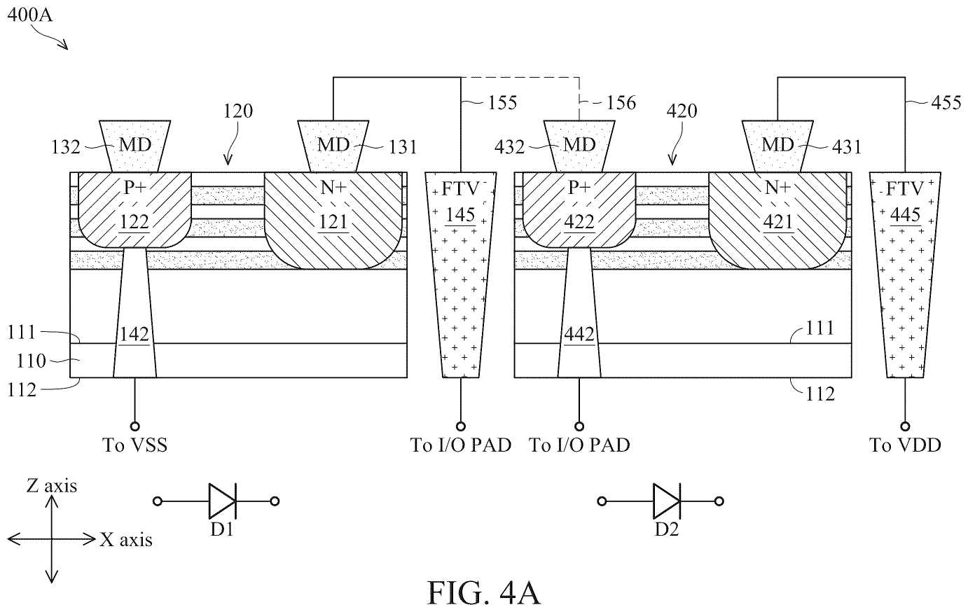

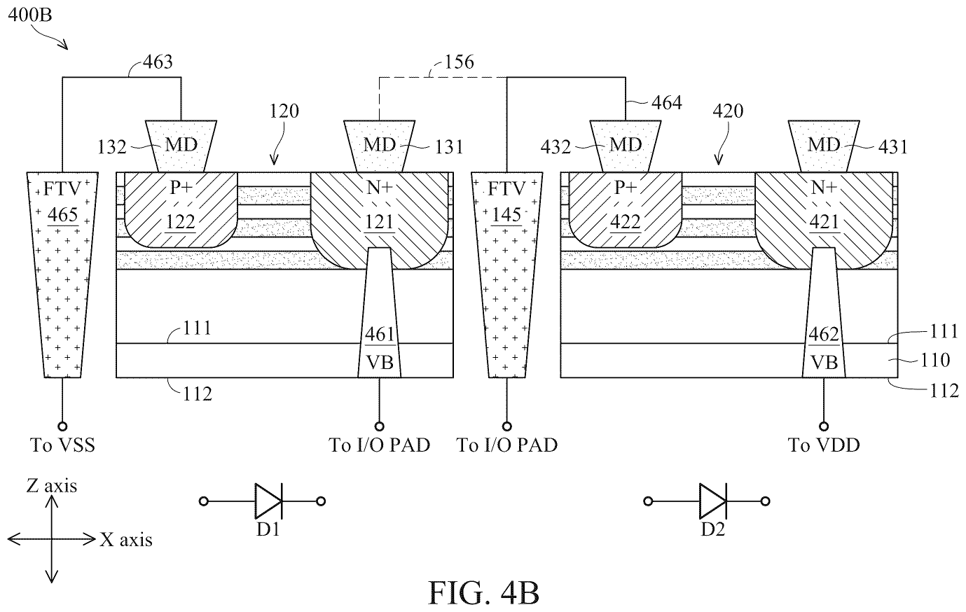

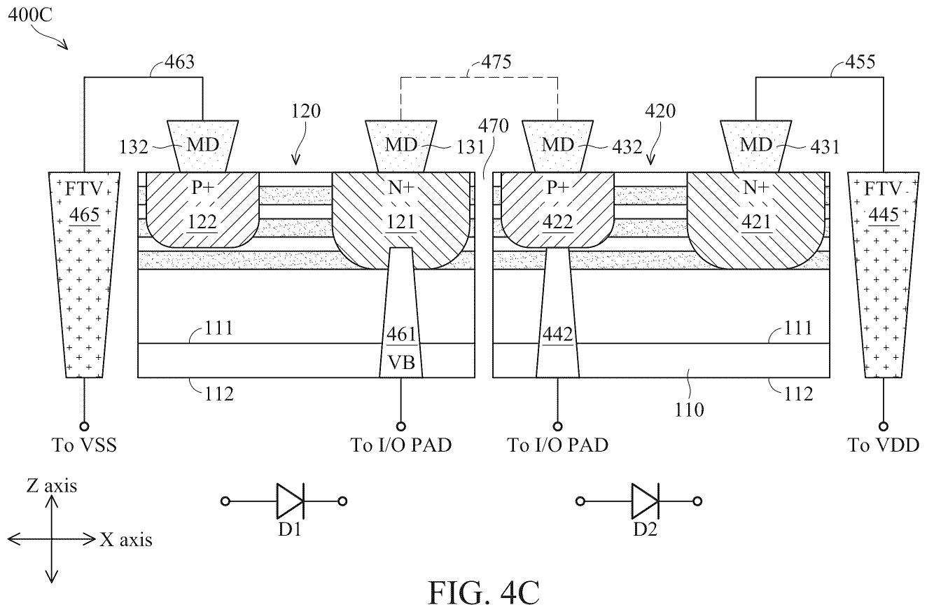

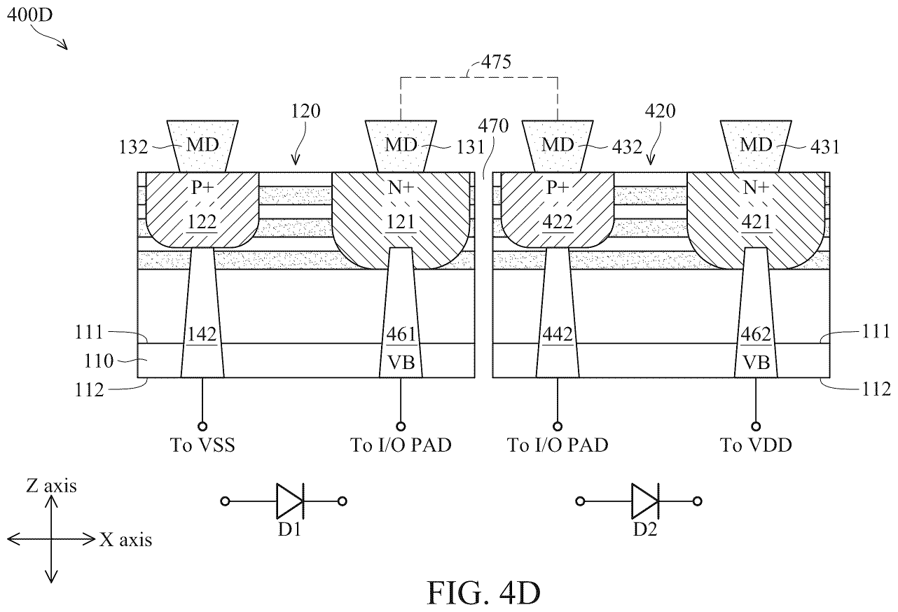

FIGS. 4A, 4B, 4C, 4D are schematic cross-sectional views of circuit regions of corresponding IC devices 400A, 400B, 400C, 400D, in accordance with some embodiments. In at least one embodiment, the IC devices 400A, 400B, 400C, 400D correspond to one or more IC devices described with respect to FIGS. 1A-1B, 2A-21, 3. For simplicity, corresponding components in FIGS. 1A-1B, 2A-21, 3, 4A-4D are designated by the same reference numerals.

Each of the IC devices 400A-400D comprises diodes D1, D2 electrically coupled between an I/O pad and a corresponding VSS power rail or VDD power rail, as described with respect to FIG. 3. The IC device 400A in FIG. 4A is an example embodiment in which both diodes D1, D2 comprise back side vias under P-doped regions. The IC device 400B in FIG. 4B is an example embodiment in which both diodes D1, D2 comprise back side vias under N-doped regions. The IC device 400C in FIG. 4C is an example embodiment in which one of the diodes D1, D2 comprises a back side via under a P-doped region, whereas the other of the diodes D1, D2 comprises a back side via under an N-doped region. The IC device 400D in FIG. 4D is an example embodiment in which each of the diodes D1, D2 comprises back side vias under both a P-doped region and an N-doped region. In some embodiments, multiple configurations described with respect to FIGS. 4A-4D are included in a single IC device.

In FIG. 4A, the diode D1 corresponds the diode D described with respect to FIG. 1A, and has an anode configured by the P-doped region 122, and a cathode configured by the N-doped region 121. The diode D2 is configured similarly to the diode D1. Components of, or related to, the diode D2 which have corresponding components of, or related to, the diode DI are designated by the reference numerals of, or related to, the diode D1 increased by three hundred. For example, for the diode D2, the IC device 400A comprises an active region 420, an N-doped region 421, a P-doped region 422, contact structures 431, 432, a back side via 442 and an FTV 445 which correspond to the active region 120, the N-doped region 121, the P-doped region 122, the contact structures 131, 132, the back side via 142 and the FTV 145. Like the FTV 145, the FTV 445 is embedded in an isolation structure (not shown). In some embodiments, the FTV 145 and the FTV 445 are embedded in the same isolation structure which extends continuously to surround both the active region 120 and the active region 420. The diode D2 is physically arranged, along the X axis, between the FTV 145 and the FTV 445. The diode D2 has an anode configured by the P-doped region 422, and a cathode configured by the N-doped region 421. In some embodiments, each of the diodes D1, D2 in the IC device 400A corresponds to a layout described with respect to one or more of FIGS. 2A-2D and/or each of the back side vias 142, 442 corresponds to one of the back side vias 242.

The IC device 400A comprises, on the back side 112 of the substrate 110, an I/O pad corresponding to the I/O pad 306, a VSS power rail corresponding to the VSS power rail 302, and a VDD power rail corresponding to the VDD power rail 304. For simplicity the VSS power rail and VDD power rail in FIGS. 4A-4D are designated as VSS and VDD. The VSS power rail on the back side is electrically coupled to the anode, e.g., the P-doped region 122, of the diode D1 by the back side via 142. The VDD power rail on the back side is electrically coupled to the cathode, e.g., the N-doped region 421, of the diode D2 by the FTV 445 and a front side conductive structure 455. In at least one embodiment, the conductive structure 455 electrically couples the FTV 445 to the N-doped region 421 through the contact structure 431 in a manner similar to that described with respect to the conductive structure 155 which electrically couples the FTV 145 to the N-doped region 121 through the contact structure 131.

In the example configuration in FIG. 4A, the I/O pad is electrically coupled to the cathode, e.g., the N-doped region 121, of the diode D1 by the FTV 145 and the front side conductive structure 155. The I/O pad is further electrically coupled to the anode, e.g., the P-doped region 422, of the diode D2 by the back side via 442. Because the cathode of the diode D1 and the anode of the diode D2 are electrically coupled on the back side at the I/O pad, there is no need for an electrical connection between the cathode of the diode D1 and the anode of the diode D2 on the front side. As a result, the conductive structure 156 for electrically coupling the cathode of the diode D1 and the anode of the diode D2 is omitted.

In some embodiments, the FTV 145 and the conductive structure 155 are omitted, and the conductive structure 156 is included in the IC device 400A to electrically couple the cathode of the diode D1 to the anode of the diode D2. As a result, the cathode of the diode DI is electrically coupled to the I/O pad on the back side through the anode of the diode D2 and the back side via 442. One or more advantages described herein are achievable by the IC device 400A, in accordance with some embodiments.

In FIG. 4B, the IC device 400B comprises back side vias 461, 462 correspondingly under the N-doped regions 121, 421. The back side vias 461, 462 extend from the back side 112, through the substrate 110, to the front side 111 to come into electrical contact with the corresponding cathodes, e.g., the N-doped region 121 and the N-doped region 421, of the diodes D1, D2. In some embodiments, each of the diodes D1, D2 in the IC device 400B corresponds to a layout described with respect to one or more of FIGS. 2E-2H and/or each of the back side vias 461, 462 corresponds to one of the back side vias 262.

The IC device 400B comprises an FTV 465 which, like the FTV 145, is embedded in an isolation structure (not shown). In some embodiments, the FTV 145 and the FTV 465 are embedded in the same isolation structure which extends continuously to surround both the active region 120 and the active region 420. The diode D1 is physically arranged, along the X axis, between the FTV 145 and the FTV 465. The VSS power rail on the back side is electrically coupled to the anode, e.g., the P-doped region 122, of the diode D1 by the FTV 465 and a front side conductive structure 463. In at least one embodiment, the conductive structure 463 electrically couples the FTV 465 to the P-doped region 122 through the contact structure 132 in a manner similar to that described with respect to the conductive structure 155. The VDD power rail on the back side is electrically coupled to the cathode, e.g., the N-doped region 421, of the diode D2 by the back side via 462.

In the example configuration in FIG. 4B, the I/O pad is electrically coupled to the cathode, e.g., the N-doped region 121, of the diode D1 by the back side via 461. The I/O pad is further electrically coupled to the anode, e.g., the P-doped region 422, of the diode D2 by the FTV 145 and a front side conductive structure 464. In at least one embodiment, the conductive structure 464 electrically couples the FTV 145 to the P-doped region 422 through the contact structure 432 in a manner similar to that described with respect to the conductive structure 155. Because the cathode of the diode D1 and the anode of the diode D2 are electrically coupled on the back side at the I/O pad, there is no need for an electrical connection between the cathode of the diode D1 and the anode of the diode D2 on the front side. As a result, the conductive structure 156 for electrically coupling the cathode of the diode D1 and the anode of the diode D2 is omitted.

In some embodiments, the FTV 145 and the conductive structure 464 are omitted, and the conductive structure 156 is included in the IC device 400B to electrically couple the cathode of the diode D1 to the anode of the diode D2. As a result, the anode of the diode D2 is electrically coupled to the I/O pad on the back side through the cathode of the diode D1 and the back side via 461. One or more advantages described herein are achievable by the IC device 400B, in accordance with some embodiments.

In FIG. 4C, the IC device 400C comprises the back side via 461 under the N-doped region 121 (e.g., the cathode) of the diode D1, and the back side via 442 under the P-doped region 422 (e.g., the anode) of the diode D2. In some embodiments, the diode D1 in the IC device 400C corresponds to a layout described with respect to one or more of FIGS. 2E-2H and/or the diode D2 in the IC device 400C corresponds to a layout described with respect to one or more of FIGS. 2A-2D.

The active region 120 of the diode D1 and the active region 420 of the diode D2 are electrically isolated and physically spaced along the X axis from each other by an isolation structure 470. In some embodiments, the isolation structure 470 is part of an isolation structure in which the FTVs 445, 465 are embedded and which extends continuously to surround both the active region 120 and the active region 420. The diodes D1, D2 are physically arranged, along the X axis, between the FTVs 445, 465. The VSS power rail on the back side is electrically coupled to the anode, e.g., the P-doped region 122, of the diode D1 by the FTV 465 and the conductive structure 463. The VDD power rail on the back side is electrically coupled to the cathode, e.g., the N-doped region 421, of the diode D2 by the FTV 445 and the conductive structure 455.

In the example configuration in FIG. 4C, the I/O pad is electrically coupled to the cathode, e.g., the N-doped region 121, of the diode D1 by the back side via 461. The I/O pad is further electrically coupled to the anode, e.g., the P-doped region 422, of the diode D2 by the back side via 442. Because the cathode of the diode D1 and the anode of the diode D2 are electrically coupled on the back side at the I/O pad, there is no need for an electrical connection between the cathode of the diode D1 and the anode of the diode D2 on the front side. As a result, the IC device 400C is free of a conductive structure 475 for electrically coupling the cathode of the diode D1 and the anode of the diode D2 on the front side.

Further, by arranging the back side via 461 under the N-doped region 121 and the back side via 442 under the P-doped region 422 in different diodes (e.g., the diodes D1, D2, respectively) or in different active regions (e.g., the active regions 120, 420, respectively), an increase (if any) of parasitic capacitance on the back side due to the close distance between the back side vias 461, 442 is not as large as when back side vias correspondingly under an N-doped region and a P-doped region are arranged in the same active region. As a result, it is possible in one or more embodiments to mitigate a concern regarding an increase in parasitic capacitance on the back side as discussed with respect to FIG. 2I. One or more advantages described herein are achievable by the IC device 400C, in accordance with some embodiments.

In FIG. 4D, the IC device 400D comprises the back side vias 142, 461, 442, 462 correspondingly under the anode and cathode of the diodes D1, D2. In some embodiments, each of the diodes D1, D2 in the IC device 400D corresponds to a layout described with respect to FIG. 2I.

The VSS power rail on the back side is electrically coupled to the anode, e.g., the P-doped region 122, of the diode D1 by the back side via 142. The VDD power rail on the back side is electrically coupled to the cathode, e.g., the N-doped region 421, of the diode D2 by the back side via 462. The I/O pad is electrically coupled to the cathode, e.g., the N-doped region 121, of the diode D1 by the back side via 461, and is further electrically coupled to the anode, e.g., the P-doped region 422, of the diode D2 by the back side via 442. Because the cathode of the diode D1 and the anode of the diode D2 are electrically coupled on the back side at the I/O pad, there is no need for an electrical connection between the cathode of the diode D1 and the anode of the diode D2 on the front side. As a result, the IC device 400D is free of a conductive structure 475 for electrically coupling the cathode of the diode D1 and the anode of the diode D2 on the front side. In the example configuration in FIG. 4D, the IC device 400D is further free of any FTV, and an associated front side conductive structure, for electrical connection to the anodes and cathodes of the diodes D1, D2.

As described with respect to FIG. 2I, in some situations, the arrangement of back side vias under both an N-doped region and a P-doped region in the same active region leads to an increase in parasitic capacitance on the back side due to the close distance along the X axis between the back side vias, e.g., between the back side vias 142, 461 or between the back side vias 442, 462. In some embodiments, despite such an increase in parasitic capacitance on the back side, an even greater reduction of parasitic capacitance on the front side is achievable, e.g., due to the omission of the FTVs and the associated front side conductive structures. As a result, the overall parasitic capacitance is still advantageously reduced, in one or more embodiments. One or more advantages described herein are achievable by the IC device 400D, in accordance with some embodiments.

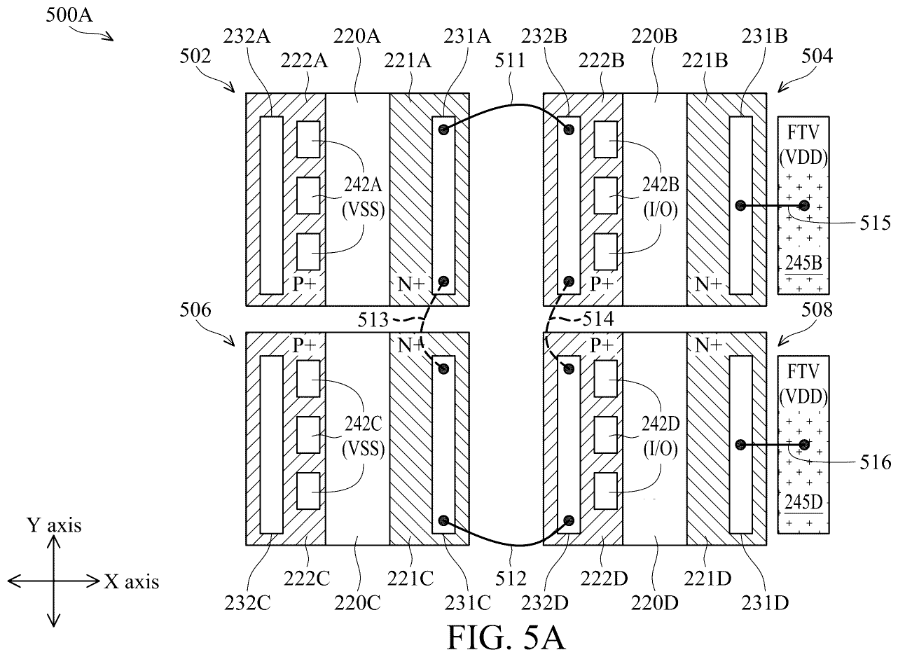

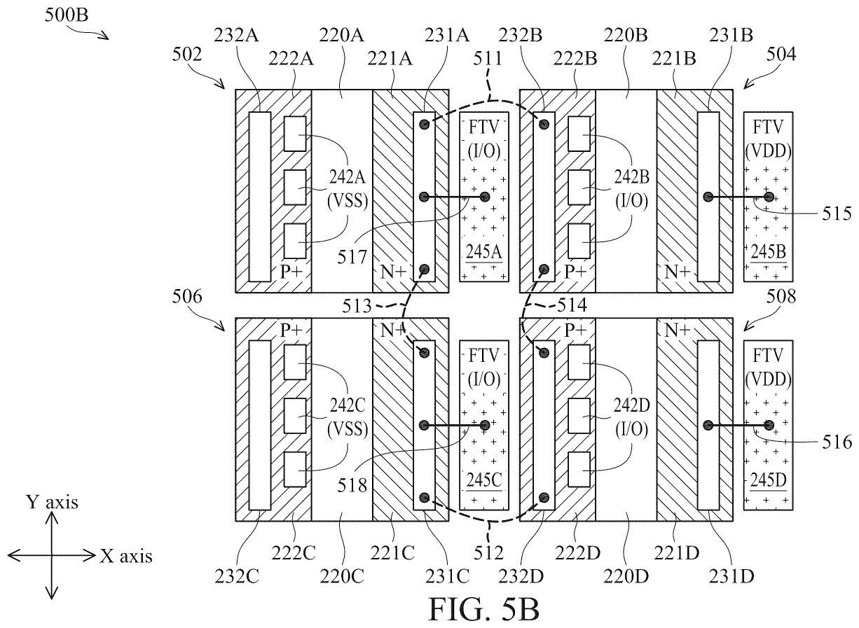

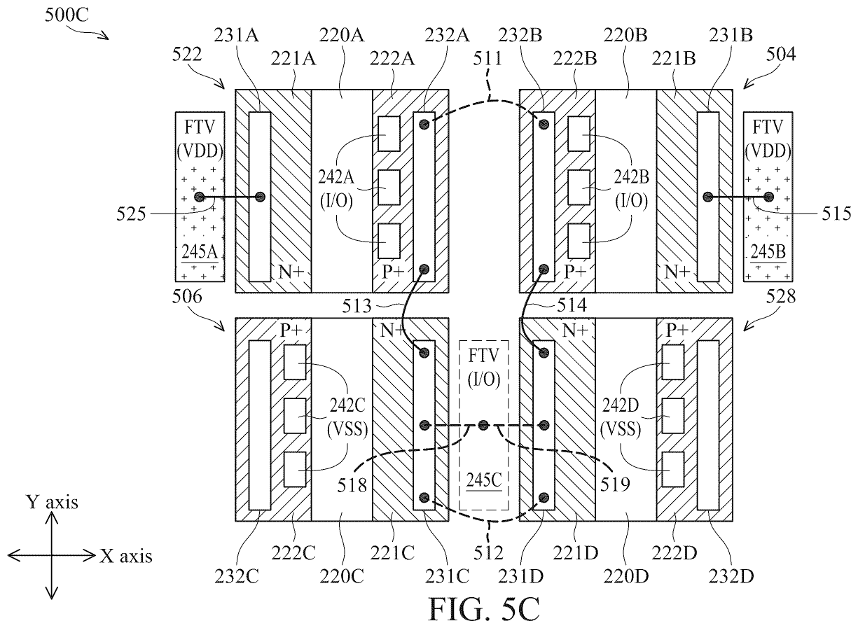

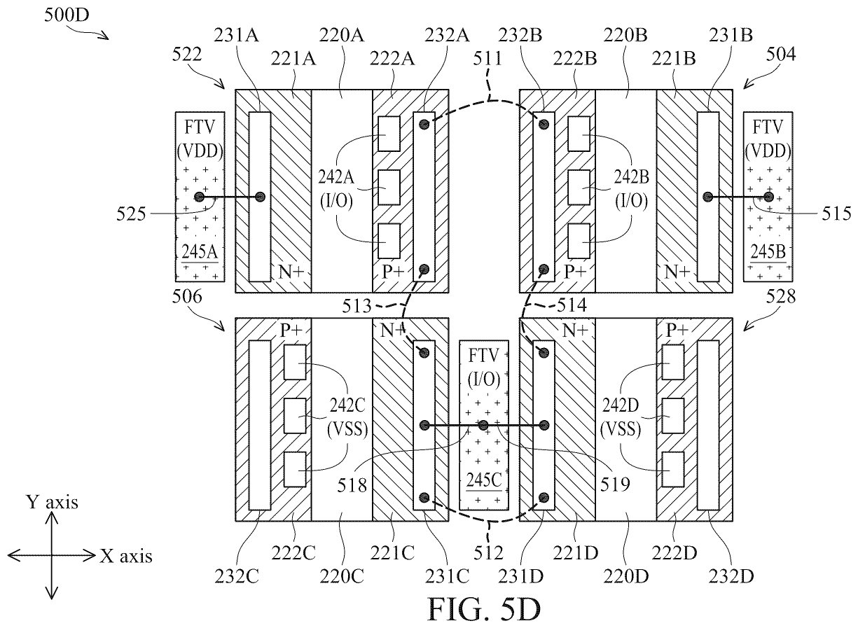

FIGS. 5A, 5B, 5C, 5D, 6A, 6B, 6C, 6D, 7A, 7B are schematic views of layouts of circuit regions of corresponding IC devices 500A, 500B, 500C, 500D, 600A, 600B, 600C, 600D, 700A, 700B, in accordance with some embodiments. In at least one embodiment, the IC devices 500A, 500B, 500C, 500D, 600A, 600B, 600C, 600D, 700A, 700B, correspond to one or more of the IC devices described with respect to FIGS. 1A-1B, 2A-2I, 3, 4A-4D. For simplicity, corresponding components in FIGS. 1A-1B, 2A-2I, 3, 4A-4D, 5A-5D, 6A-6D, 7A-7B are designated by the same reference numerals. Also for simplicity, in FIGS. 5A-5D, 6A-6D, 7A-7B, I/O pads are designated as “I/O”, VSS power rails or conductors configured to carry or provide VSS are designated as “VSS”, and VDD power rails or conductors configured to carry or provide VDD are designated as “VDD”.

The IC devices 500A, 500B, 500C, 500D are example embodiments in which back side vias are arranged under P-doped regions in a manner similar to those described with respect to one or more of FIGS. 2A-2D, 4A. The IC devices 600A, 600B, 600C, 600D are example embodiments in which back side vias are arranged under N-doped regions in a manner similar to those described with respect to one or more of FIGS. 2E-2H, 4B. The IC devices 700A, 700B are example embodiments in which back side vias are arranged under both P-doped regions and N-doped regions, in a manner similar to those described with respect to FIG. 4C. In some embodiments, multiple configurations described with respect to FIGS. 5A-5D, 6A-6D, 7A-7B are included in a single IC device.

In FIG. 5A, the IC device 500A comprises a plurality of diodes arranged in an array having multiple rows and columns. For example, the plurality of diodes comprises diodes 502, 504, 506, 508 arranged in a 2×2 array. Other numbers of diodes in an array and/or other array configurations are within the scopes of various embodiments. For example, a larger number of diodes in an ESD protection circuit configures the ESD protection circuit to be able to discharge a larger ESD current.

In the example configuration in FIG. 5A, each of the diodes 502, 504, 506, 508 is an instance of the diode described with respect to FIG. 2A. In some embodiments, one or more of the diodes 502, 504, 506, 508 include one or more instances of one or more diodes described with respect to FIGS. 2A-2D. For simplicity, components of the diodes 502, 504, 506, 508 are designated by the reference numerals of corresponding components described with respect to FIG. 2A, with added suffixes “A”, “B”, “C”, “D”. For example, back side vias of the diodes 502, 504, 506, 508, which correspond to the back side vias 242 in FIG. 2A, are correspondingly designated as back side vias 242A, 242B, 242C, 242D.

In some embodiments, the IC device 500A comprises an isolation structure (not shown) which extends continuously around each of the diodes 502, 504, 506, 508 and FTVs 245B, 245D to isolate the diodes 502, 504, 506, 508 and the FTVs 245B, 245D from each other.

The diodes 502, 504 are electrically coupled in a manner similar to that described with respect to FIG. 4A, in a situation where the FTV 145 is omitted. Specifically, a P-doped region 222A of the diode 502 is electrically coupled to VSS by the back side vias 242A, and an N-doped region 221A of the diode 502 is electrically coupled to a P-doped region 222B of the diode 504 by a front side conductive structure 511. The P-doped region 222B of the diode 504 is electrically coupled to the I/O pad by the back side vias 242B, and an N-doped region 221B of the diode 504 is electrically coupled to VDD by a front side conductive structure 515 and the FTV 245B. In some embodiments, the conductive structures 511, 515 correspond to the conductive structures 156, 455.

The diodes 506, 508 are electrically coupled in a manner similar to that described with respect to FIG. 4A, in a situation where the FTV 145 is omitted. Specifically, a P-doped region 222C of the diode 506 is electrically coupled to VSS by the back side vias 242C, and an N-doped region 221C of the diode 506 is electrically coupled to a P-doped region 222D of the diode 508 by a front side conductive structure 512. The P-doped region 222D of the diode 508 is electrically coupled to the I/O pad by the back side vias 242D, and an N-doped region 221D of the diode 508 is electrically coupled to VDD by a front side conductive structure 516 and the FTV 245D. In some embodiments, the conductive structures 512, 516 correspond to the conductive structures 156, 455.

Because the N-doped regions 221A, 221C and the P-doped regions 222B, 222D are all electrically coupled to the same I/O pad, in one or more embodiments, there is no need for a front side conductive structure 513 electrically coupling the N-doped regions 221A, 221C with each other and/or for a front side conductive structure 514 electrically coupling the P-doped regions 222B, 222D with each other. In other words, the conductive structures 513, 514 are optional. In some embodiments, at least one of the optional conductive structures 513, 514 is included in the IC device 500A.

In FIG. 5B, the IC device 500B, compared to the IC device 500A, further comprises FTVs 245A, 245C and associated front side conductive structures 517, 518. The conductive structures 511, 512 in the IC device 500B are optional. In some embodiments, at least one of the optional conductive structures 511-514 is included in the IC device 500B.

The diodes 502, 504 and the diodes 506, 508 are electrically coupled in a manner similar to that described with respect to FIG. 4A, in a situation where the FTV 145 is included. Specifically, the N-doped region 221A of the diode 502 is electrically coupled to the I/O pad (and hence to the P-doped region 222B of the diode 504) by the conductive structure 517 and the FTV 245A. Similarly, the N-doped region 221C of the diode 506 is electrically coupled to the I/O pad (and hence to the P-doped region 222D of the diode 508) by the conductive structure 518 and the FTV 245C. In some embodiments, the conductive structures 517, 518 correspond to the conductive structure 155.

In FIGS. 5A, 5B, diodes in a same column are electrically coupled in parallel to effectively configure a diode with a greater current handling capability. For example, the diodes 502, 506 are in the same column and are coupled in parallel with each other, between the I/O pad and VSS.

Effectively, the diodes 502, 506 together configure the diode D1 described with respect to FIG. 3 and the diode D1 so configured has a current handling capability about twice the current handling capability of each of the diodes 502, 506. Similarly, the diodes 504, 508 are in the same column and are coupled in parallel with each other, between the I/O pad and VDD. Effectively, the diodes 504, 508 together configure the diode D2 described with respect to FIG. 3.

Example embodiments where diodes in a same row are electrically coupled in parallel to effectively configure a diode with a greater current handling capability are described with respect to FIGS. 5C, 5D.

In FIG. 5C, the IC device 500C comprises a plurality of diodes arranged in an array having multiple rows and columns. For example, the plurality of diodes comprises diodes 522, 504, 506, 528 arranged in a 2×2 array. In the example configuration in FIG. 5C, each of the diodes 522, 504, 506, 528 is an instance of the diode described with respect to FIG. 2A, the diode 522 is a version of the diode 502 flipped across the Y axis, and the diode 528 is a version of the diode 508 flipped across the Y axis. In some embodiments, one or more of the diodes 522, 504, 506, 528 include one or more instances of one or more diodes described with respect to FIGS. 2A-2D.

The diodes 522, 504 are electrically coupled as follows. The P-doped region 222A of the diode 522 is electrically coupled to the I/O pad by the back side vias 242A, and the N-doped region 221A of the diode 522 is electrically coupled to VDD by a front side conductive structure 525 and an FTV 245A. The P-doped region 222B of the diode 504 is electrically coupled to the I/O pad by the back side vias 242B, and the N-doped region 221B of the diode 504 is electrically coupled to VDD by the conductive structure 515 and the FTV 245B. In some embodiments, the conductive structures 515, 525 correspond to the conductive structures 155, 455.

The diodes 506, 528 are electrically coupled as follows. The P-doped region 222C of the diode 506 is electrically coupled to VSS by the back side vias 242C, and the N-doped region 221C of the diode 506 is electrically coupled to the P-doped region 222A of the diode 522 by a front side conductive structure 513. The P-doped region 222D of the diode 528 is electrically coupled to VSS by the back side vias 242D, and the N-doped region 221D of the diode 528 is electrically coupled to the P-doped region 222B of the diode 504 by a front side conductive structure 514. In some embodiments, the conductive structures 513, 514 correspond to the conductive structure 156.

Because the N-doped regions 221C, 221D and the P-doped regions 222A, 222B are all electrically coupled to the same I/O pad, in one or more embodiments, there is no need for a front side conductive structure 511 electrically coupling the P-doped regions 222A, 222B with each other and/or for a front side conductive structure 512 electrically coupling the N-doped regions 221C, 221D with each other. For a similar reason, in some embodiments, there is no need for an FTV 245C arranged between the diodes 506, 528 and/or associated front side conductive structures 518, 519 for electrically coupling the I/O pad to the N-doped regions 221C, 221D. In other words, the conductive structures 511, 512, 518, 519 and FTV 245C are optional. In some embodiments, one or more of the optional FTV 245C and conductive structures 511, 512, 518, 519 are included in the IC device 500C.

In FIG. 5D, the IC device 500D, compared to the IC device 500C, further comprises the FTV 245C and the associated front side conductive structures 518, 519. The conductive structures 513, 514 in the IC device 500D are optional. In some embodiments, at least one of the optional conductive structures 511-514 is included in the IC device 500D.

Compared to the IC device 500C, in the IC device 500D, the N-doped region 221C is electrically coupled to the I/O pad by the conductive structure 518 and the FTV 245C, and the N-doped region 221D is electrically coupled to the I/O pad by the conductive structure 519 and the FTV 245C.

In some embodiments, the conductive structures 518, 519 correspond to the conductive structure 155.

In FIGS. 5C, 5D, diodes in a same row are electrically coupled in parallel to effectively configure a diode with a greater current handling capability. For example, the diodes 522, 504 are in the same row and are coupled in parallel with each other, between the I/O pad and VDD. Effectively, the diodes 522, 504 together configure the diode D2 described with respect to FIG. 3 and the diode D2 so configured has a current handling capability about twice the current handling capability of each of the diodes 522, 504. Similarly, the diodes 506, 528 are in the same row and are coupled in parallel with each other, between the I/O pad and VSS. Effectively, the diodes 506, 528 together configure the diode D1 described with respect to FIG. 3. One or more advantages described herein are achievable by the IC devices 500A-500D, in accordance with some embodiments.

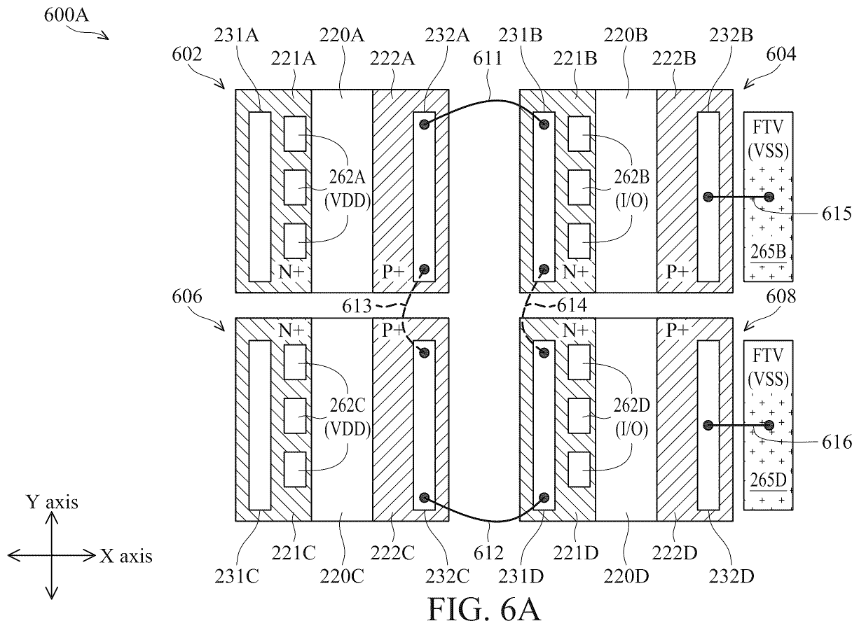

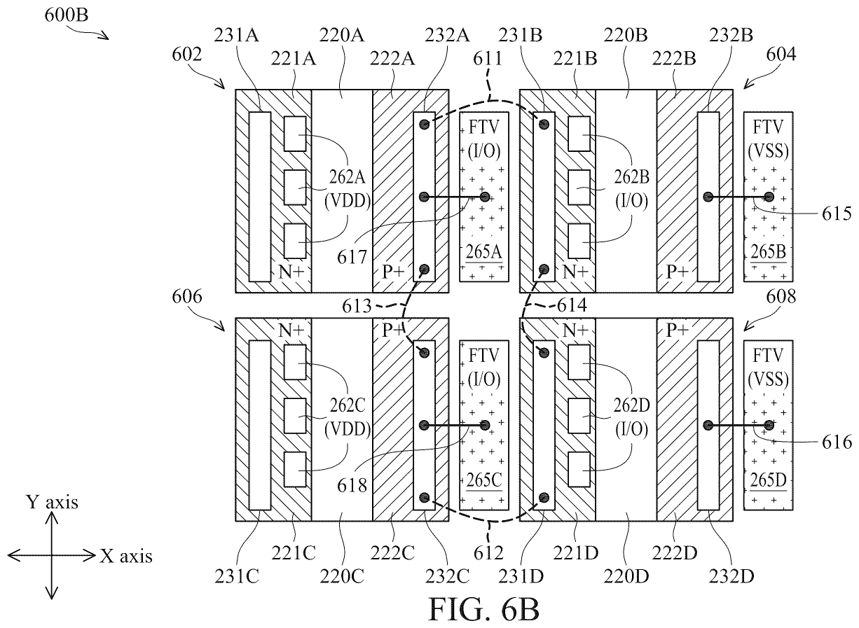

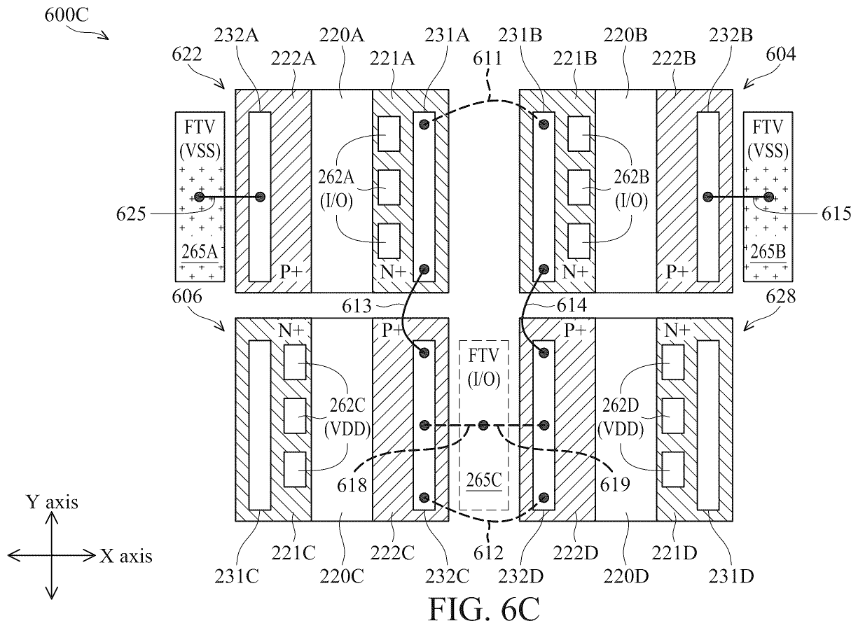

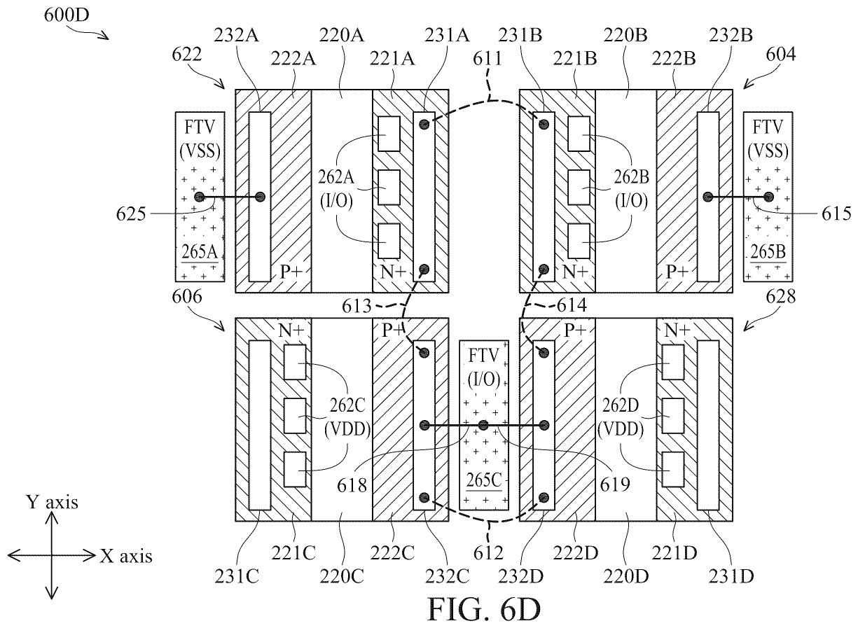

In the IC devices 500A-500D, back side vias are arranged under P-doped regions. Example embodiments where back side vias are arranged under N-doped regions are described with respect to FIGS. 6A-6D.

In FIG. 6A, the IC device 600A comprises a plurality of diodes arranged in an array having multiple rows and columns. For example, the plurality of diodes comprises diodes 602, 604, 606, 608 arranged in a 2×2 array.

In the example configuration in FIG. 6A, each of the diodes 602, 604, 606, 608 is an instance of the diode described with respect to FIG. 2E where the diode described with respect to FIG. 2E is flipped across the Y axis. In some embodiments, one or more of the diodes 602, 604, 606, 608 include one or more instances of one or more diodes described with respect to FIGS. 2E-2H. For simplicity, components of the diodes 602, 604, 606, 608 are designated by the reference numerals of corresponding components described with respect to FIG. 2E, with added suffixes “A”, “B”, “C”, “D”. For example, back side vias of the diodes 602, 604, 606, 608, which correspond to the back side vias 262 in FIG. 2E, are correspondingly designated as back side vias 262A, 262B, 262C, 262D.

In some embodiments, the IC device 600A comprises an isolation structure (not shown) which extends continuously around each of the diodes 602, 604, 606, 608 and FTVs 265B, 265D to isolate the diodes 602, 604, 606, 608 and the FTVs 265B, 265D from each other.

The diodes 602, 604 are electrically coupled in a manner similar to that described with respect to FIG. 4B, in a situation where the FTV 145 is omitted. Specifically, an N-doped region 221A of the diode 602 is electrically coupled to VDD by the back side vias 262A, and a P-doped region 222A of the diode 602 is electrically coupled to an N-doped region 221B of the diode 604 by a front side conductive structure 611. The N-doped region 221B of the diode 604 is electrically coupled to the I/O pad by the back side vias 262B, and a P-doped region 222B of the diode 604 is electrically coupled to VSS by a front side conductive structure 615 and the FTV 265B. In some embodiments, the conductive structures 611, 615 correspond to the conductive structures 156, 463.

The diodes 606, 608 are electrically coupled in a manner similar to that described with respect to FIG. 4B, in a situation where the FTV 145 is omitted. Specifically, an N-doped region 221C of the diode 606 is electrically coupled to VDD by the back side vias 262C, and a P-doped region 222C of the diode 606 is electrically coupled to an N-doped region 221D of the diode 608 by a front side conductive structure 612. The N-doped region 221D of the diode 608 is electrically coupled to the I/O pad by the back side vias 262D, and a P-doped region 222D of the diode 608 is electrically coupled to VSS by a front side conductive structure 616 and the FTV 265D. In some embodiments, the conductive structures 612, 616 correspond to the conductive structures 156, 463.

Because the N-doped regions 221B, 221D and the P-doped regions 222A, 222C are all electrically coupled to the same I/O pad, in one or more embodiments, there is no need for a front side conductive structure 613 electrically coupling the P-doped regions 222A, 222C with each other and/or for a front side conductive structure 614 electrically coupling the N-doped regions 221B, 221D with each other. In other words, the conductive structures 613, 614 are optional. In some embodiments, at least one of the optional conductive structures 613, 614 is included in the IC device 600A.

In FIG. 6B, the IC device 600B, compared to the IC device 600A, further comprises FTVs 265A, 265C and associated front side conductive structures 617, 618. The conductive structures 611, 612 in the IC device 600B are optional. In some embodiments, at least one of the optional conductive structures 611-614 is included in the IC device 600B.

The diodes 602, 604 and the diodes 606, 608 are electrically coupled in a manner similar to that described with respect to FIG. 4B, in a situation where the FTV 145 is included. Specifically, the P-doped region 222A of the diode 602 is electrically coupled to the I/O pad (and hence to the N-doped region 221B of the diode 604) by the conductive structure 617 and the FTV 265A. Similarly, the P-doped region 222C of the diode 606 is electrically coupled to the I/O pad (and hence to the N-doped region 221D of the diode 608) by the conductive structure 618 and the FTV 265C. In some embodiments, the conductive structures 617, 618 correspond to the conductive structure 464.

In FIGS. 6A, 6B, diodes in a same column are electrically coupled in parallel to effectively configure a diode with a greater current handling capability. For example, the diodes 602, 606 are in the same column and are coupled in parallel with each other, between the I/O pad and VDD.

Effectively, the diodes 602, 606 together configure the diode D2 described with respect to FIG. 3 and the diode D2 so configured has a current handling capability about twice the current handling capability of each of the diodes 602, 606. Similarly, the diodes 604, 608 are in the same column and are coupled in parallel with each other, between the I/O pad and VSS. Effectively, the diodes 604, 608 together configure the diode D1 described with respect to FIG. 3.

Example embodiments where diodes in a same row are electrically coupled in parallel to effectively configure a diode with a greater current handling capability are described with respect to FIGS. 6C, 6D.

In FIG. 6C, the IC device 600C comprises a plurality of diodes arranged in an array having multiple rows and columns. For example, the plurality of diodes comprises diodes 622, 604, 606, 628 arranged in a 2×2 array. In the example configuration in FIG. 6C, each of the diodes 622, 604, 606, 628 is an instance of the diode described with respect to FIG. 2E, the diode 622 is a version of the diode 602 flipped across the Y axis, and the diode 628 is a version of the diode 608 flipped across the Y axis. In some embodiments, one or more of the diodes 622, 604, 606, 628 include one or more instances of one or more diodes described with respect to FIGS. 2E-2H.

The diodes 622, 604 are electrically coupled as follows. The N-doped region 221A of the diode 622 is electrically coupled to the I/O pad by the back side vias 262A, and the P-doped region 222A of the diode 622 is electrically coupled to VSS by a front side conductive structure 625 and an FTV 265A. The N-doped region 221B of the diode 604 is electrically coupled to the I/O pad by the back side vias 262B, and the P-doped region 222B of the diode 604 is electrically coupled to VSS by the conductive structure 615 and the FTV 265B. In some embodiments, the conductive structures 615, 625 correspond to the conductive structures 463, 464.

The diodes 606, 628 are electrically coupled as follows. The N-doped region 221C of the diode 606 is electrically coupled to VDD by the back side vias 262C, and the P-doped region 222C of the diode 606 is electrically coupled to the N-doped region 221A of the diode 622 by a front side conductive structure 613. The N-doped region 221D of the diode 628 is electrically coupled to VDD by the back side vias 262D, and the P-doped region 222D of the diode 628 is electrically coupled to the N-doped region 221B of the diode 604 by a front side conductive structure 614. In some embodiments, the conductive structures 613, 614 correspond to the conductive structure 156.

Because the N-doped regions 221A, 221B and the P-doped regions 222C, 222D are all electrically coupled to the same I/O pad, in one or more embodiments, there is no need for a front side conductive structure 611 electrically coupling the N-doped regions 221A, 221B with each other and/or for a front side conductive structure 612 electrically coupling the P-doped regions 222C, 222D with each other. For a similar reason, in some embodiments, there is no need for an FTV 265C arranged between the diodes 606, 628 and/or associated front side conductive structures 618, 619 for electrically coupling the I/O pad to the P-doped regions 222C, 222D. In other words, the conductive structures 611, 612, 618, 619 and FTV 265C are optional. In some embodiments, one or more of the optional FTV 265C and conductive structures 611, 612, 618, 619 are included in the IC device 600C.

In FIG. 6D, the IC device 600D, compared to the IC device 600C, further comprises the FTV 265C and the associated front side conductive structures 618, 619. The conductive structures 613, 614 in the IC device 600D are optional. In some embodiments, at least one of the optional conductive structures 611-614 is included in the IC device 600D.

Compared to the IC device 600C, in the IC device 600D, the P-doped region 222C is electrically coupled to the I/O pad by the conductive structure 618 and the FTV 265C, and the P-doped region 222D is electrically coupled to the I/O pad by the conductive structure 619 and the FTV 265C.

In some embodiments, the conductive structures 618, 619 correspond to the conductive structure 464.

In FIGS. 6C, 6D, diodes in a same row are electrically coupled in parallel to effectively configure a diode with a greater current handling capability. For example, the diodes 622, 604 are in the same row and are coupled in parallel with each other, between the I/O pad and VSS. Effectively, the diodes 622, 604 together configure the diode D1 described with respect to FIG. 3 and the diode D1 so configured has a current handling capability about twice the current handling capability of each of the diodes 622, 604. Similarly, the diodes 606, 628 are in the same row and are coupled in parallel with each other, between the I/O pad and VDD. Effectively, the diodes 606, 628 together configure the diode D2 described with respect to FIG. 3. One or more advantages described herein are achievable by the IC devices 600A-600D, in accordance with some embodiments.

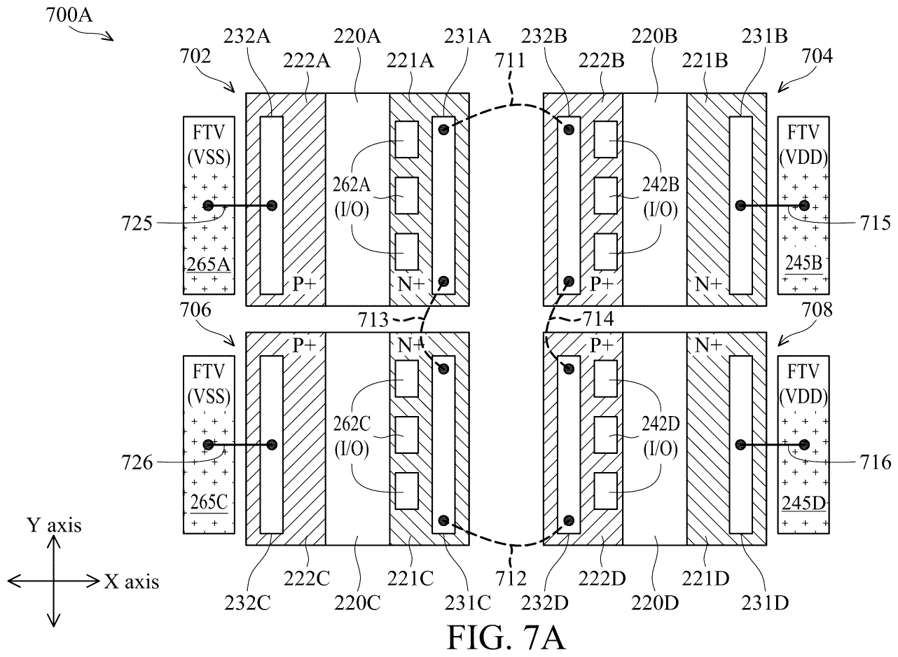

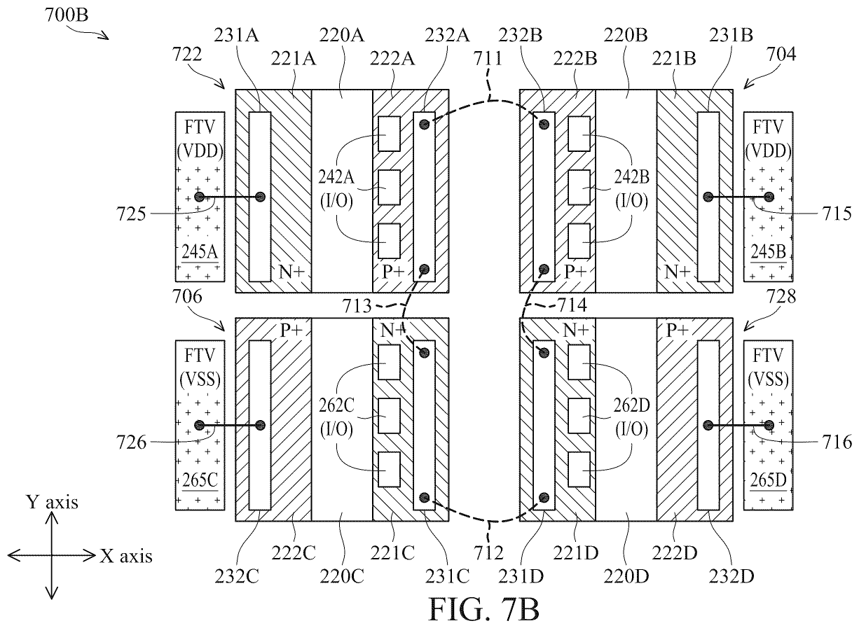

In the IC devices 500A-500D, back side vias are arranged under P-doped regions, whereas in the IC devices 600A-600D, back side vias are arranged under N-doped regions. Example embodiments where back side vias are arranged under both N-doped regions and P-doped regions are described with respect to FIGS. 7A-7B.

In FIG. 7A, the IC device 700A comprises a plurality of diodes arranged in an array having multiple rows and columns. For example, the plurality of diodes comprises diodes 702, 704, 706, 708 arranged in a 2×2 array.

In the example configuration in FIG. 7A, each of the diodes 704, 708 is an instance of the diode described with respect to FIG. 2A, and each of the diodes 702, 706 is an instance of the diode described with respect to FIG. 2E. In some embodiments, one or more of the diodes 702, 704, 706, 708 include one or more instances of one or more diodes described with respect to FIGS. 2A-2H. For simplicity, components of the diodes 702, 704, 706, 708 are designated by the reference numerals of corresponding components described with respect to FIG. 2A or FIG. 2E, with added suffixes “A”, “B”, “C”, “D”. For example, back side vias of the diodes 702, 706, which correspond to the back side vias 262 in FIG. 2E, are correspondingly designated as back side vias 262A, 262C, whereas back side vias of the diodes 704, 708, which correspond to the back side vias 242 in FIG. 2A, are correspondingly designated as back side vias 242B, 242D.

In some embodiments, the IC device 700A comprises an isolation structure (not shown) which extends continuously around each of the diodes 702, 704, 706, 708 and FTVs 265A, 245B, 265C, 245D to isolate the diodes 702, 704, 706, 708 and the FTVs 265A, 245B, 265C, 245D from each other.

The diodes 702, 704 are electrically coupled as follows. An N-doped region 221A of the diode 702 is electrically coupled to the I/O pad by the back side vias 262A, and a P-doped region 222A of the diode 702 is electrically coupled to VSS by a front side conductive structure 725 and an FTV 265A. The P-doped region 222B of the diode 704 is electrically coupled to the I/O pad by the back side vias 242B, and an N-doped region 221B of the diode 704 is electrically coupled to VDD by a front side conductive structure 715 and an FTV 245B. In some embodiments, the conductive structures 715, 725 correspond to the conductive structures 155, 463.

The diodes 706, 708 are electrically coupled as follows. An N-doped region 221C of the diode 706 is electrically coupled to the I/O pad by the back side vias 262C, and a P-doped region 222C of the diode 706 is electrically coupled to VSS by a front side conductive structure 726 and an FTV 265C. The P-doped region 222D of the diode 708 is electrically coupled to the I/O pad by the back side vias 242D, and an N-doped region 221D of the diode 708 is electrically coupled to VDD by a front side conductive structure 716 and the FTV 245D. In some embodiments, the conductive structures 716, 726 correspond to the conductive structures 155, 463.

Because the N-doped regions 221A, 221C and the P-doped regions 222B, 222D are all electrically coupled to the same I/O pad, in one or more embodiments, there is no need for a front side conductive structure 711 electrically coupling the N-doped region 221A with the P-doped region 222B and/or for a front side conductive structure 712 electrically coupling the N-doped region 221C with the P-doped region 222D, and/or for a front side conductive structure 713 electrically coupling the N-doped regions 221A, 221C with each other and/or for a front side conductive structure 714 electrically coupling the P-doped regions 222B, 222D with each other. In other words, the conductive structures 711-714 are optional. In some embodiments, at least one of the optional conductive structures 711-714 is included in the IC device 700A.

In FIG. 7A, diodes in a same column are electrically coupled in parallel to effectively configure a diode with a greater current handling capability. For example, the diodes 702, 706 are in the same column and are coupled in parallel with each other, between the I/O pad and VSS.

Effectively, the diodes 702, 706 together configure the diode D1 described with respect to FIG. 3.

Similarly, the diodes 704, 708 are in the same column and are coupled in parallel with each other, between the I/O pad and VDD. Effectively, the diodes 704, 708 together configure the diode D2 described with respect to FIG. 3.

In FIG. 7B, the IC device 700B comprises a plurality of diodes arranged in an array having multiple rows and columns. For example, the plurality of diodes comprises diodes 722, 704, 706, 728 arranged in a 2×2 array. In the example configuration in FIG. 7B, the diode 722 corresponds to the diode 522, and the diode 728 corresponds to the diode 608. In some embodiments, one or more of the diodes 722, 704, 706, 728 include one or more instances of one or more diodes described with respect to FIGS. 2E-2H.

The diodes 722, 704 are electrically coupled as follows. The P-doped region 222A of the diode 722 is electrically coupled to the I/O pad by the back side vias 242A, and the N-doped region 221A of the diode 722 is electrically coupled to VDD by the conductive structure 725 and an FTV 245A. The P-doped region 222B of the diode 704 is electrically coupled to the I/O pad by the back side vias 242B, and the N-doped region 221B of the diode 704 is electrically coupled to VDD by the conductive structure 715 and the FTV 245B. In some embodiments, the conductive structures 715, 725 correspond to the conductive structure 155.

The diodes 706, 728 are electrically coupled as follows. The N-doped region 221C of the diode 706 is electrically coupled to the I/O pad by the back side vias 262C, and the P-doped region 222C of the diode 706 is electrically coupled to VSS by the conductive structure 726 and the FTV 265C. The N-doped region 221D of the diode 728 is electrically coupled to the I/O pad by the back side vias 262D, and the P-doped region 222D of the diode 728 is electrically coupled to VSS by the conductive structure 716 and an FTV 265D. In some embodiments, the conductive structures 716, 726 correspond to the conductive structure 463.

Because the N-doped regions 221C, 221D and the P-doped regions 222A, 222B are all electrically coupled to the same I/O pad, in one or more embodiments, there is no need for one or more of the conductive structures 711-714. In other words, the conductive structures 711-714 are optional. In some embodiments, one or more of the optional conductive structures 711-714 are included in the IC device 700B.

In FIG. 7B, diodes in a same row are electrically coupled in parallel to effectively configure a diode with a greater current handling capability. For example, the diodes 722, 704 are in the same row and are coupled in parallel with each other, between the I/O pad and VDD. Effectively, the diodes 722, 704 together configure the diode D2 described with respect to FIG. 3. Similarly, the diodes 706, 728 are in the same row and are coupled in parallel with each other, between the I/O pad and VSS. Effectively, the diodes 706, 728 together configure the diode D1 described with respect to FIG. 3. One or more advantages described herein are achievable by the IC devices 700A, 700B, in accordance with some embodiments.

In some embodiments, the layout in each of FIGS. 5A-5D, 6A-6D, 7A-7B is obtained in an APR operation and/or by an APR tool. For example, the APR tool is configured to read, from a cell library, one or more diode cells as described with respect to FIGS. 2A-2I, place multiple instances of the one or more diode cells in an array, and perform routing to electrically couple the placed diode cells into one or more diodes with greater current handling capability, as described herein with respect to one or more of FIGS. 5A-5D, 6A-6D, 7A-7B. In some embodiments, the APR tool is further configured to place one or more FTVs and perform routing for such FTVs to provide electrical connections from the front side to the back side, as described herein. In some embodiments, a resulting layout obtained from the APR operation is stored on a non-transitory computer-readable medium.

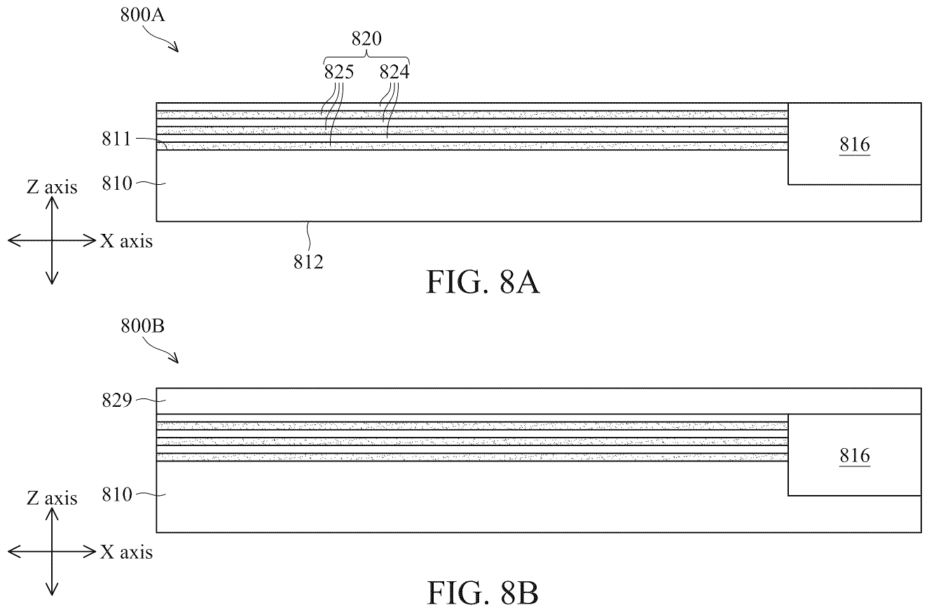

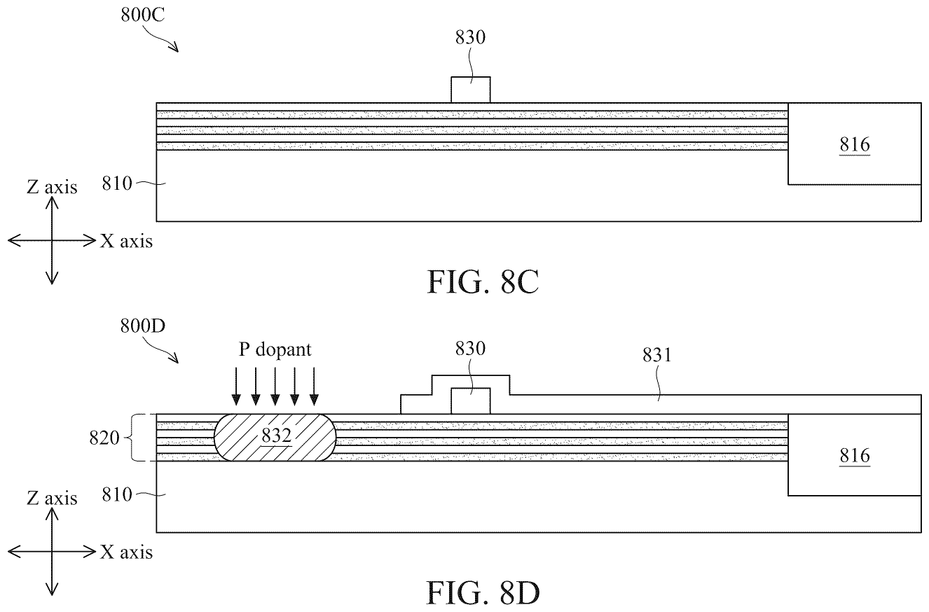

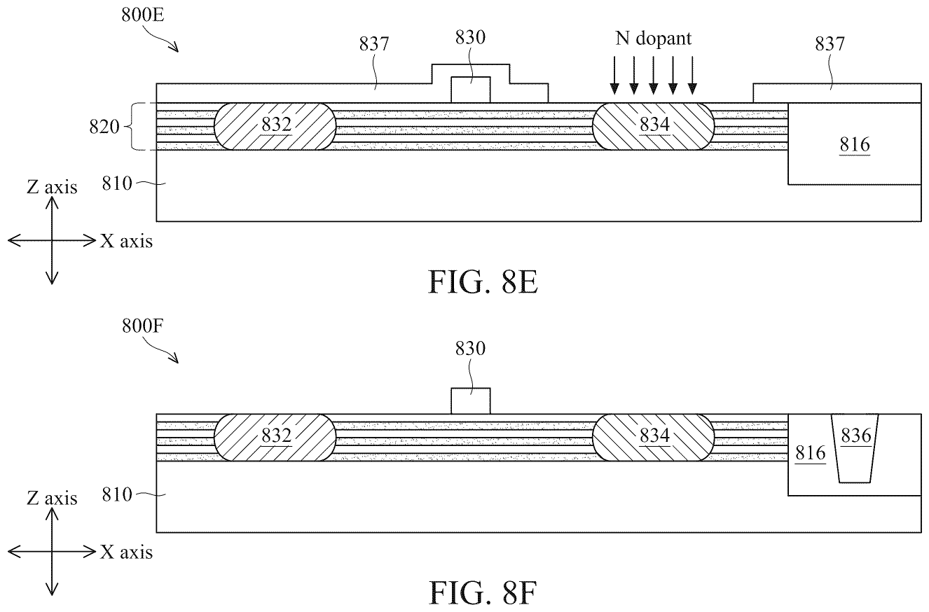

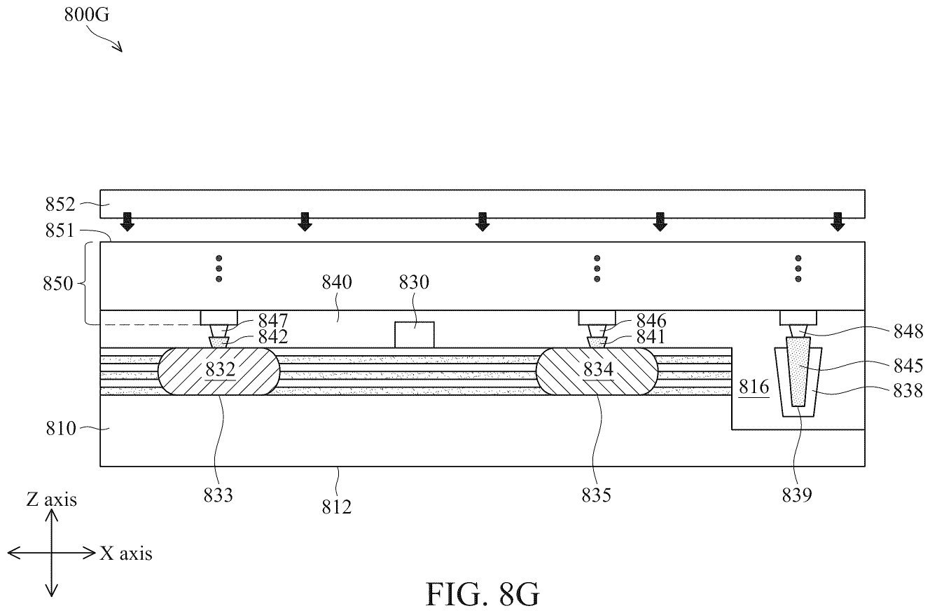

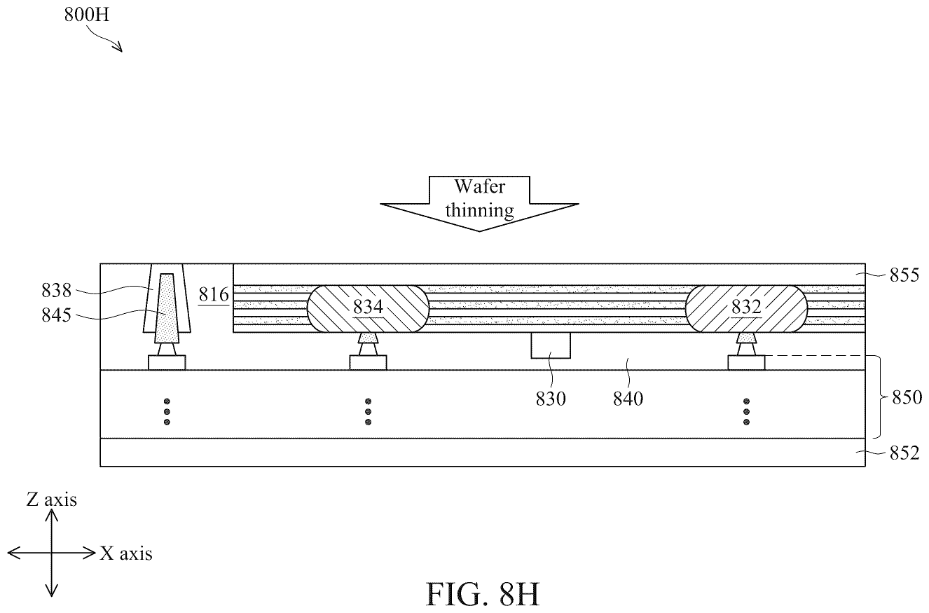

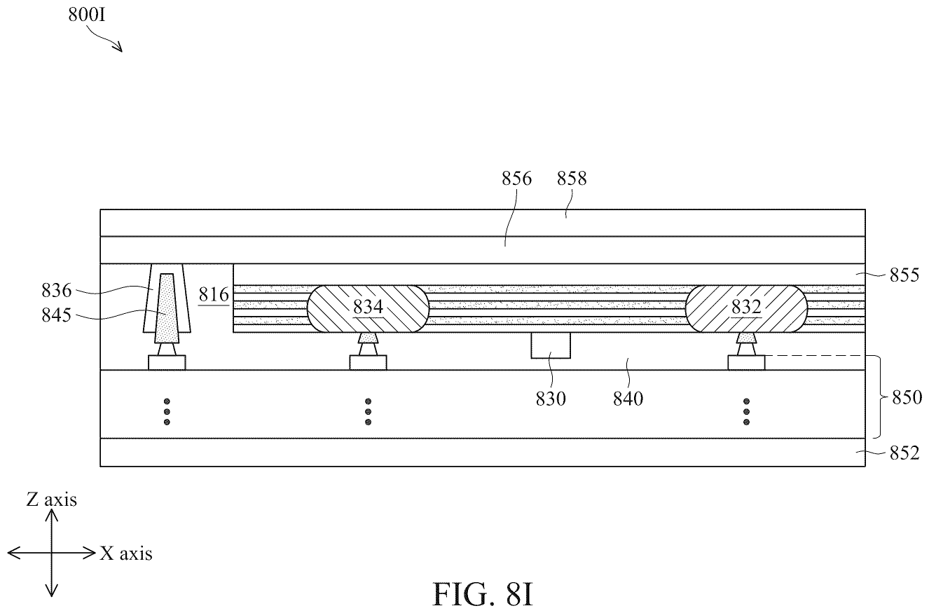

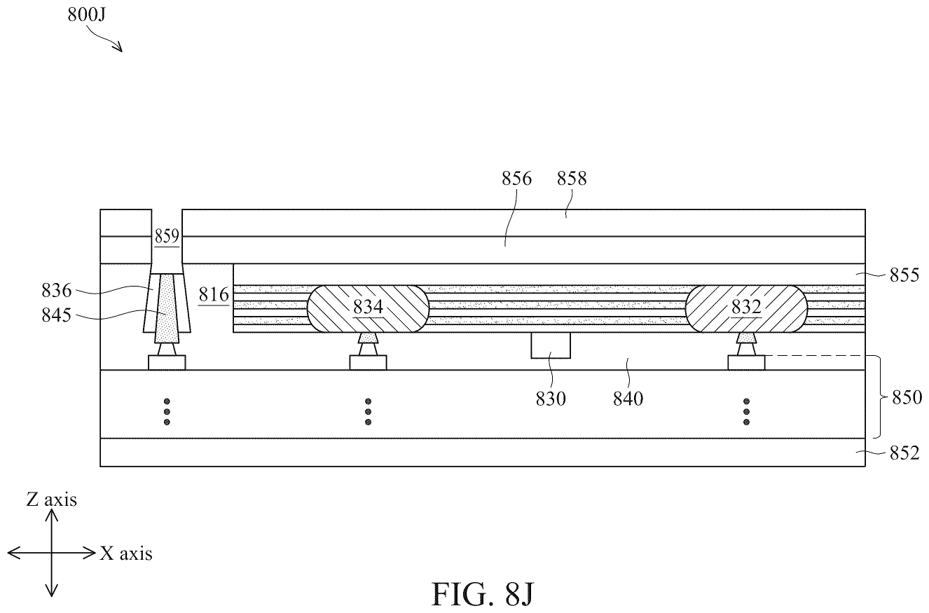

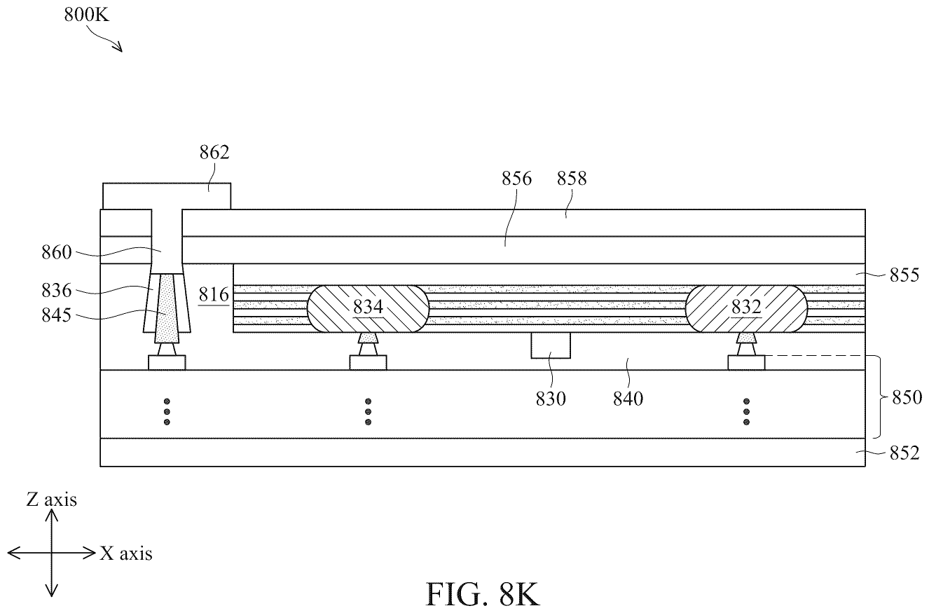

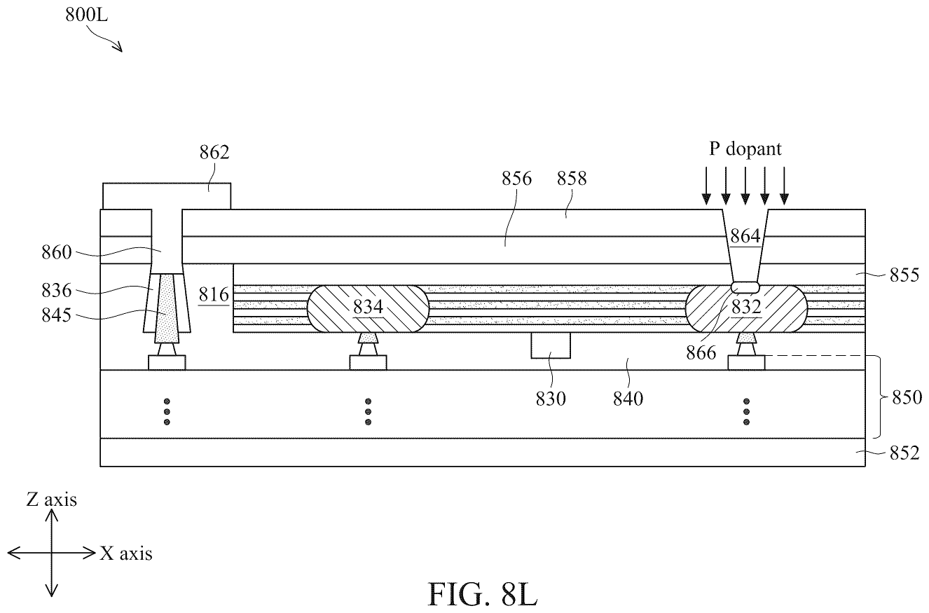

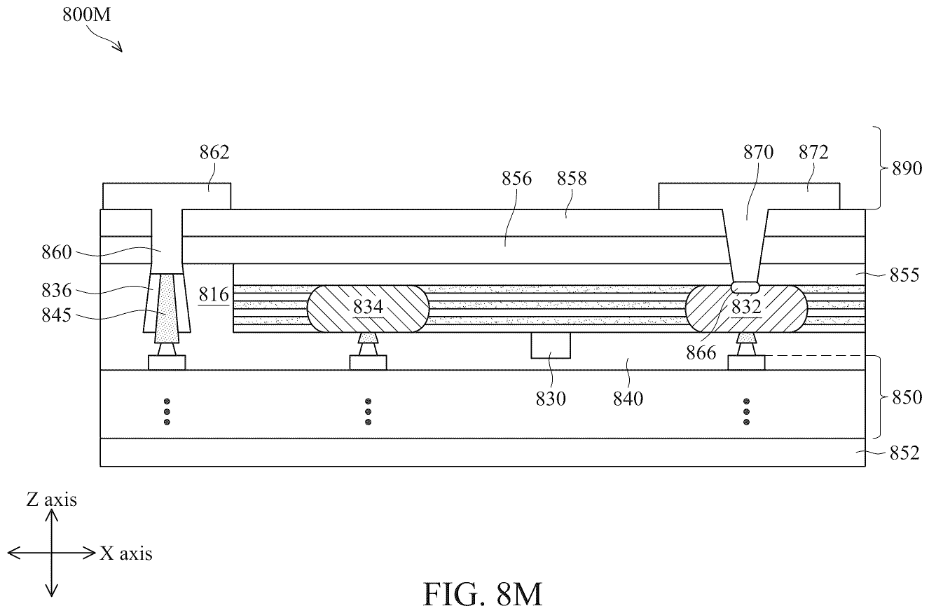

FIGS. 8A, 8B, 8C, 8D, 8E, 8F, 8G, 8H, 8I, 8J, 8K, 8L, 8M are schematic cross-sectional views of a circuit region of an IC device at various stages in a manufacturing process, in accordance with some embodiments. In at least one embodiment, the manufacturing process described with respect to FIGS. 8A-8M are applicable to fabricate one or more of the IC devices described herein with respect to FIGS. 1A-1B, 2A-2I, 3, 4A-4D, 5A-5D, 6A-6D, 7A-7B. In some embodiments, the manufacturing process described herein is compatible with gate-all-around (GAA) processes although a gate replacement process is omitted.

In FIG. 8A, an example manufacturing process starts from a substrate 810. In some embodiments, at least a part of the substrate 810 corresponds to the substrate 110 and/or the semiconductor layer 115. In the example configuration in FIG. 8A, the substrate 810 is a semiconductor substrate. In some embodiments, the substrate 810 is a P-type substrate. In some embodiments, the substrate 810 is an N-type substrate. In some embodiments, substrate 810 includes an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In some embodiments, the substrate 810 includes a doped epitaxial layer or a buried layer. In some embodiments, the compound semiconductor substrate has a multilayer structure, or the substrate includes a multilayer compound semiconductor structure.

In at least one embodiment, the substrate 810 comprises an SOI substrate comprising a semiconductor layer and an insulation layer over the semiconductor layer. In some embodiments, the SOI substrate further comprises a front side semiconductor layer, e.g., a Si layer, over the insulation layer. This front side semiconductor layer is later patterned to become a lowest layer of a multilayer stack, as described herein. In at least one embodiment, an SOI substrate having an insulation layer buried between a semiconductor substrate and a front side semiconductor layer is manufactured using one or more SOI processes. Examples of SOI processes include, but are not limited to, separation by implanted oxygen (SIMOX), wafer bonding followed by precision grinding and polishing, ion split including implantation of hydrogen to form a weakened region within a silicon wafer, or the like. Other SOI processes are within the scopes of various embodiments. Other substrate configurations are within the scopes of various embodiments.

The substrate 810 has a front side 811 and a back side 812 opposite the front side 811 along a thickness direction of the substrate 810, i.e., along the Z axis. Alternating layers of a first semiconductor material and a second semiconductor material different from the first semiconductor material are sequentially deposited over the front side 811 of the substrate 810. In some embodiments, the first semiconductor material comprises silicon (Si), and the second semiconductor material comprises SiGe. As a result, alternating SiGe/Si/SiGe/Si layers are stacked over the front side 811 of the substrate 810 to form a multilayer stack. A region where the multilayer stack is formed corresponds to an active region 820. In at least one embodiment, the active region 820 or a part thereof corresponds to the active region 120. In the example configuration in FIG. 8A, the multilayer stack comprises Si layers 824 alternatingly arranged with SiGe layers 825. In some embodiments, the alternating layers SiGe/Si/SiGe/Si are formed by an epitaxy process. Example epitaxy processes include, but are not limited to, CVD deposition, ultra-high vacuum CVD (UHV-CVD), low-pressure CVD (LPCVD), plasma-enhanced CVD (PECVD), selective epitaxial growth (SEG), or the like. Other materials and/or manufacturing processes for the alternating layers of the different first and second semiconductor materials are within the scopes of various embodiments.

An isolation structure 816 (e.g., an STI region) is formed in one or more trenches between the active region 820 and other active regions of the IC device to physically separate and electrically isolate the active regions from each other. In at least one embodiment, the isolation structure 816 or a part thereof corresponds to the isolation structure 146. In some embodiments, one or more dielectric materials, such as SiO and/or SiN, are deposited in and over the trenches, e.g., by chemical vapor deposition (CVD), plasma enhanced CVD (PECVD), atomic layer deposition (ALD), physical vapor deposition (PVD), thermal oxidation, or the like. Subsequently, the dielectric material is recessed, e.g., by etching and/or chemical mechanical polishing (CMP) to form the isolation structure 816. A resulting structure 800A is thus obtained.

In FIG. 8B, a dummy gate layer 829 is deposited over the structure 800A. An example material of the dummy gate layer 829 is polysilicon. In some embodiments, the dummy gate layer 829 comprises one or more further material layers, e.g., a gate dielectric layer (e.g., SiO2, or the like) under the polysilicon and/or a hard mask layer (e.g., SiN, SiCN, SiO, or the like) over the polysilicon. In at least one embodiment, the dummy gate layer 829 is formed by deposition processes, lithography processes, etching processes, combinations thereof, or the like. A resulting structure 800B is thus obtained.

In FIG. 8C, the dummy gate layer 829 is etched, e.g., by using a mask, to obtain a gate 830. A resulting structure 800C is thus obtained. In at least one embodiment, the gate 830 corresponds to the gate 130. In some embodiments, the formation of the gate 830 as described with respect to FIGS. 8B, 8C is omitted.

In FIG. 8D, a photoresist (PR) layer 831 is deposited over the gate 830 to cover an area of the active region 820 where an N-doped region is to be formed, while exposing another area of the active region 820 where a P-doped region is to be formed. Example processes for depositing the photoresist layer 831 include, but are not limited to, CVD, PECVD, ALD, PVD, or the like. Subsequently, an ion implantation process is performed to implant a P-type dopant, e.g., boron, into the exposed area of the active region 820 to form a P-doped region 832. A resulting structure 800D is thus obtained. In at least one embodiment, the P-doped region 832 corresponds to the P-doped region 122.

In FIG. 8E, a photoresist layer 837 is deposited over the gate 830, the P-doped region 832 and the isolation structure 816, while exposing the area of the active region 820 where an N-doped region is to be formed. Subsequently, an ion implantation process is performed to implant an N-type dopant, e.g., phosphorous, into the exposed area of the active region 820 to form an N-doped region 834. A resulting structure 800E is thus obtained. In at least one embodiment, the N-doped region 834 corresponds to the N-doped region 121.

In FIG. 8F, an opening is etched in the isolation structure 816, e.g., by using a cut-metal-gate (CMG) mask. The opening is then filled by a dielectric material, such as SiN, SiOx, to obtain a pre-FTV structure 836 embedded in the isolation structure 816. A resulting structure 800F is thus obtained.

In FIG. 8G, various contact structures, VD vias, as well as metal layers and via layers of a redistribution structure 850 are formed over the structure 800F to form one or more front side conductive structures as described herein. For example, in one or more embodiments, a front side conductive structure similar to the conductive structure 155 is formed in the redistribution structure 850 to electrically couple the VD vias 846, 848 with each other, thereby electrically coupling the N-doped region 834 with the FTV 845. In at least one embodiment, the redistribution structure 850 corresponds to the redistribution structure 150. The formation of contact structures, VD vias, and the redistribution structure 850 includes a combination of photolithography, material removal and deposition processes. Examples of the material removal process include, but are not limited to, wet etching, dry etching, laser drilling, or the like, or another suitable etching process. The openings created by the material removal process are then filled with a conductive material, e.g., copper, aluminum, titanium, nickel, tungsten, or the like, by using CVD, PVD, sputtering, ALD, or the like.

In some embodiments, before the formation of contact structures and VD vias, a gate replacement process in performed in other regions of the IC device being manufactured, to replace polysilicon gates with metal to form metal gates for various transistors of functional circuits in the IC device. In some embodiments, such a gate replacement process is not performed for the gate 830, which remains a polysilicon gate.

In the example configuration in FIG. 8G, contact structures 841, 842 are formed correspondingly over the N-doped region 834 and the P-doped region 832. In some embodiments, an FTV 845 is formed at the same time, in the same processes and using the same material as the contact structures 841, 842. For example, an FTV opening is etched into the pre-FTV structure 836, and is then filled with the same material of the contact structures 841, 842, to obtain the FTV 845. A remaining part of the pre-FTV structure 836 configures an FTV insulation layer 838 around and below the FTV 845. The FTV 845 has a bottommost portion 839 located, along the thickness direction (Z axis), below bottommost portions 833, 835 of the P-doped region 832 and the N-doped region 834. The described FTV formation is an example. Other FTV formation processes are within the scopes of various embodiments. VD vias 846, 847, 848 are formed correspondingly over the contact structures 841, 842 and FTV 845. In at least one embodiment, the contact structures 841, 842, VD via 846 and the FTV 845 correspond to the contact structures 131, 132, VD via 133 and the FTV 145. The metal layers and via layers of the redistribution structure 850 are sequentially formed over the VD vias. The contact structures, VD vias and the metal layers and via layers of the redistribution structure 850 are embedded in various dielectric layers referred to as interlayer dielectric (ILD) or intermetal dielectric (IMD) 840. A resulting structure 800G is thus obtained. A carrier wafer 852 is temporarily and/or releasably bonded to a top surface 851 of the redistribution structure 850.

In FIG. 8H, the structure 800G and the carrier wafer 852 bonded thereto are flipped upside down, and a wafer thinning process is performed from the back side 812 of the substrate 810 to remove a portion of the substrate 810. In some embodiments, the wafer thinning process includes a grinding operation, a polishing operation (such as, chemical mechanical polishing (CMP)), or the like. In the example configuration in FIG. 8H, the wafer thinning process is stopped when the FTV insulation layer 838 is exposed. In at least one embodiment, the FTV insulation layer 838 functions as an etch stop layer for this purpose. At the end of the wafer thinning process, a substrate portion 855 of the substrate 810 remains. A resulting structure 800H is thus obtained. In at least one embodiment, the substrate portion 855 corresponds to the semiconductor layer 115.

In FIG. 8I, one or more back side dielectric layers are deposited over the structure 800H. For example, a first dielectric layer 856 (e.g., SiN) is deposited over the structure 800H, and a second dielectric layer 858 (e.g., an oxide) is deposited over the first dielectric layer 856. A resulting structure 800I is thus obtained. In at least one embodiment, a combination of the dielectric layers 856, 858 corresponds to the substrate 110.

In FIG. 8J, an opening 859 is etched through the dielectric layers 856, 858 to expose the FTV 845. A resulting structure 800J is thus obtained.

In FIG. 8K, a conductive material is filled in the opening 859 to form a conductive plug 860 in electrical and physical contact with the FTV 845. The conductive material is further deposited over the dielectric layer 858 and patterned to obtain a back side conductor 862. A resulting structure 800K is thus obtained. In at least one embodiment, the conductive plug 860 and back side conductor 862 configure at least a part of the back side conductive structure 165. In some embodiments, the back side conductor 862 is a metal pattern in the BM0 layer. In some embodiments, when an FTV is not required, the FTV formation described with respect to FIGS. 8F-8K is omitted.

In FIG. 8L, an opening 864 is etched through the dielectric layers 856, 858 to expose an area of the P-doped region 832. An ion implantation process is performed to implant a P-type dopant, e.g., boron, into the exposed area of the P-doped region 832 to form a contact feature 866. A resulting structure 800L is thus obtained.

In FIG. 8M, a conductive material is filled in the opening 864 to form a back side via 870 in electrical and physical contact with the P-doped region 832. In some embodiments, the contact feature 866 promotes the electrical and physical contact between the back side via 870 and the P-doped region 832. The conductive material is further deposited over the dielectric layer 858 and patterned to obtain a back side conductor 872. In at least one embodiment, the back side conductor 872 configures at least a part of the back side conductive structure 162. In some embodiments, the back side conductor 872 is a metal pattern in the BM0 layer.

Subsequently, various back side via layers and back side metal layers are sequentially deposited and patterned over the back side conductors 862, 872 and the dielectric layer 858, to configure a back side redistribution structure 890. In at least one embodiment, the redistribution structure 890 corresponds to the redistribution structure 160, and/or includes further patterns and vias of back side conductive structures corresponding to the conductive structures 162, 165. A resulting structure 800M is thus obtained. In some embodiments, the carrier wafer 852 is released from the redistribution structure 850 of the structure 800M, and one or more further processes are performed to finish fabrication of the IC device.

In some embodiments, one or more advantages described herein are achievable by one or more IC devices manufactured by the process described with respect to one or more of FIGS. 8A-8M. Although the described manufacturing processes include formation of nanosheet devices in one or more embodiments, other types of devices, e.g., nanowire, FinFET, planar, or the like, are within the scopes of various embodiments.

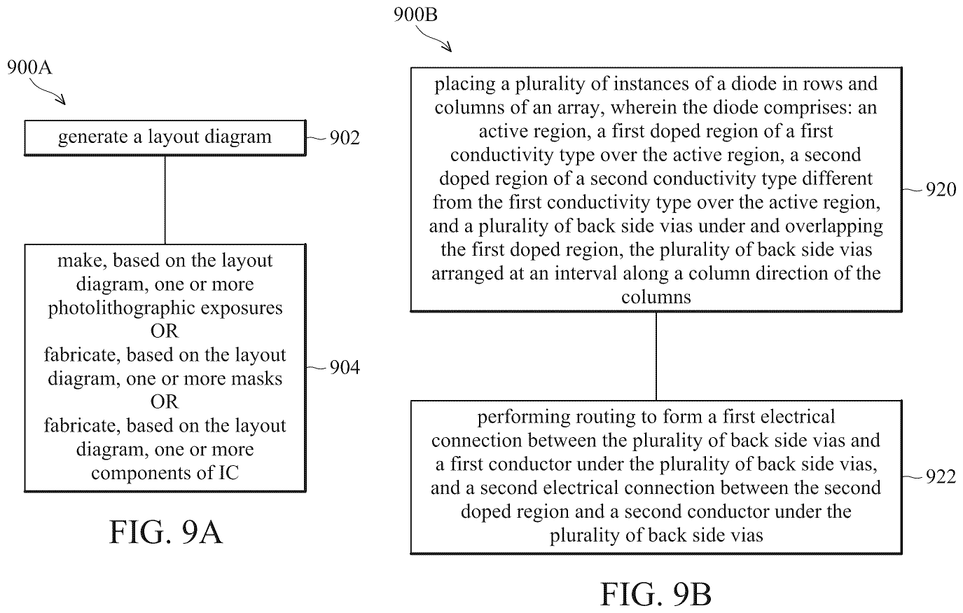

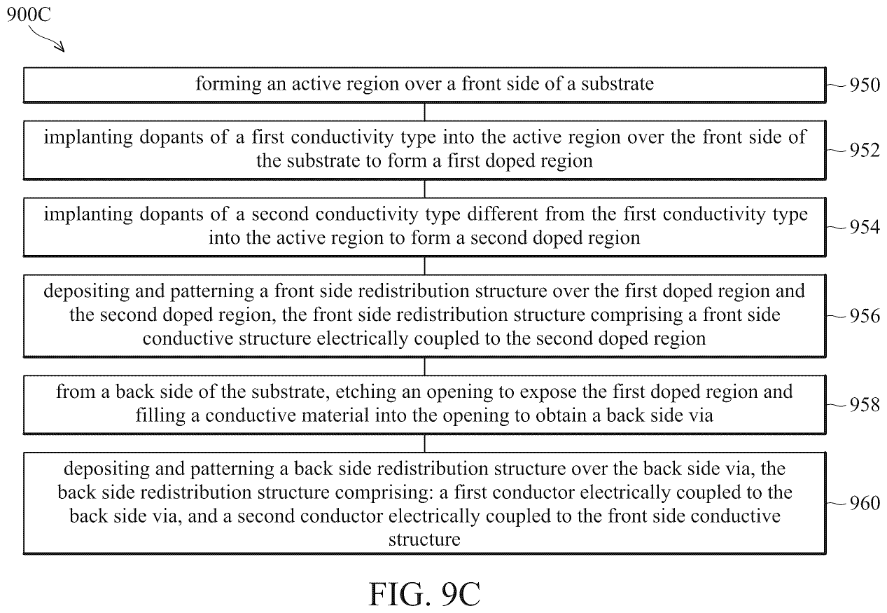

FIG. 9A is a flowchart of a method 900A of generating a layout and using the layout to manufacture an IC device, in accordance with some embodiments. Method 900A is implementable, for example, using an EDA system and/or an integrated circuit (IC) manufacturing system as described herein, in accordance with some embodiments. Regarding method 900A, examples of the layout include the layouts disclosed herein, or the like. Examples of an IC device to be manufactured according to method 900A include one or more of the IC devices disclosed herein. Method 900A comprises operations 902, 904.

At operation 902, a layout is generated which, among other things, includes at least one diode with a back side via under at least one of an anode or a cathode thereof, as described herein. Examples of operation 902 are described with respect to FIG. 9B.

At operation 904, based on the layout, at least one of (A) one or more photolithographic exposures are made or (B) one or more semiconductor masks are fabricated or (C) one or more components in a layer of an IC device are fabricated. Examples of operation 904 are described with respect to FIG. 9C.

FIG. 9B is a flowchart of a method 900B of generating a layout for an IC device, in accordance with some embodiments. The method 900B is performed at least partially by a processor. In some embodiments, the method 900B is performed to generate one or more layouts described herein, e.g., in an APR operation. The method 900B comprises operations 920, 922.

At operation 920, a plurality of instances of a diode is placed in rows and columns of an array. The diode comprises an active region, a first doped region of a first conductivity type over the active region, a second doped region of a second conductivity type different from the first conductivity type over the active region, and a plurality of back side vias under and overlapping the first doped region, the plurality of back side vias arranged at an interval along a column direction of the columns. For example, as described with respect to FIGS. 5A-5D, 6A-6D, 7A-7B, multiple instances of a diode is placed in rows and columns of an array. In a non-liming example described with respect to FIG. 5A, diodes 502, 504, 506, 508, which are all instances of the diode described with respect to FIG. 2A, are arranged in a 2×2 array. The diode 502, for example, comprises an active region 220A, N-doped region 221A and P-doped region 222A over the active region 220A, and a plurality of back side vias 242A under and overlapping the P-doped region 222A. The plurality of back side vias 242A is arranged at an interval along a column direction of the columns, e.g., the Y axis in FIG. 5A.

At operation 922, routing is performed to form a first electrical connection between the plurality of back side vias and a first conductor under the plurality of back side vias, and a second electrical connection between the second doped region and a second conductor under the plurality of back side vias. For example, as described with respect to FIG. 5A, the plurality of back side vias 242A is routed to be electrically coupled to VSS, and the N-doped region 221A is routed to be electrically coupled to an I/O conductor. As described with respect to FIG. 1A, the routing corresponds to, e.g., back side conductive structures 162, 165 for electrically coupling a back side via 142 and a doped region 121 to corresponding conductors 164, 167 under the back side via 142. In some embodiments, a layout obtained by the described APR operation is stored on a non-transitory computer-readable recording medium, e.g., for later retrieval and use in manufacturing IC devices, as described with respect to FIG. 9C. One or more advantages described herein are achievable by a layout generated by the method 900B and/or by one or more IC devices manufactured in accordance with such layout, in accordance with some embodiments.

FIG. 9C is a flowchart of a method 900C of manufacturing an IC device, in accordance with some embodiments. In some embodiments, the method 900C is performed to manufacture one or more IC devices described herein. The method 900C comprises operations 950, 952, 954, 956, 958, 960.

At operation 950, an active region is formed over a front side of a substrate. For example, as described with respect to FIG. 8A, an active region 820 is formed over a front side 811 of a substrate 810.

At operation 952, dopants of a first conductivity type are implanted into the active region over the front side of the substrate to form a first doped region. For example, as described with respect to FIG. 8D, P-type dopants are implanted into the active region 820 to form a P-doped region 832.

At operation 954, dopants of a second conductivity type different from the first conductivity type are implanted into the active region to form a second doped region. For example, as described with respect to FIG. 8E, N-type dopants are implanted into the active region 820 to form an N-doped region 834.

At operation 956, a front side redistribution structure is formed, by depositing and patterning, over the first doped region and the second doped region, the front side redistribution structure comprising a front side conductive structure electrically coupled to the second doped region. For example, as described with respect to FIG. 8G, a front side redistribution structure 850 is formed over the P-doped region 832 and the N-doped region 834. The redistribution structure 850 comprises a front side conductive structure electrically coupled to the N-doped region 834. Examples of a front side conductive structure include, but are not limited to, the conductive structure 155 and the conductive structure 156 described with respect to FIG. 1A.

At operation 958, an opening is etched from a back side of the substrate to expose the first doped region, and a conductive material is filled into the opening to obtain a back side via. For example, as described with respect to FIG. 8L, an opening 864 is etched from a back side of the substrate (e.g., the dielectric layers 856, 858 and/or the substrate portion 855) to expose the P-doped region 832. As described with respect to FIG. 8M, and a conductive material is filled into the opening 864 to obtain a back side via 870.

At operation 960, a back side redistribution structure is formed, by depositing and patterning, over the back side via, the back side redistribution structure comprising: a first conductor electrically coupled to the back side via, and a second conductor electrically coupled to the front side conductive structure. For example, as described with respect to FIG. 8M, a back side redistribution structure 890 is formed over the back side via 870. In some embodiments, the redistribution structure 890 corresponds to the redistribution structure 160 described with respect to FIG. 1A. The redistribution structure 160 comprises a conductor 164 electrically coupled to a back side via 142, and a second conductor 167 electrically coupled to a front side conductive structure 155. In at least one embodiment, one or more advantages described herein are achievable by an IC device manufactured in accordance with the method 900C.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

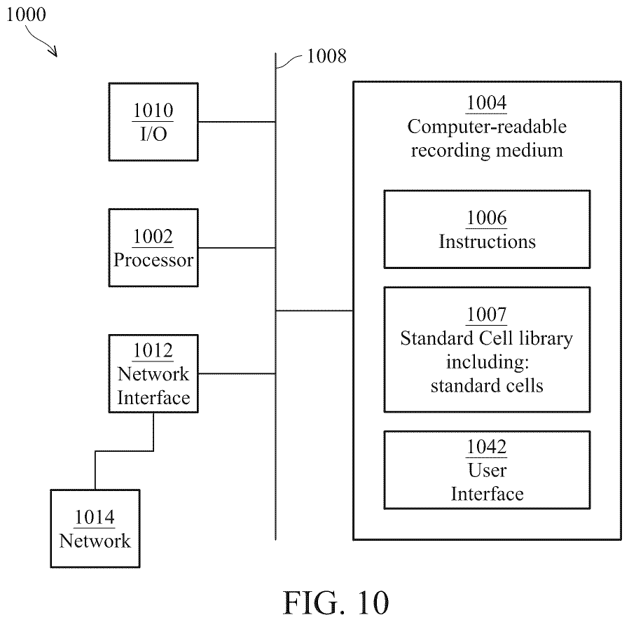

FIG. 10 is a block diagram of an electronic design automation (EDA) system 1000 in accordance with some embodiments.

In some embodiments, EDA system 1000 includes an APR system. Methods described herein of designing layouts represent wire routing arrangements, in accordance with one or more embodiments, are implementable, for example, using EDA system 1000, in accordance with some embodiments.

In some embodiments, EDA system 1000 is a general purpose computing device including a hardware processor 1002 and a non-transitory, computer-readable recording medium 1004. Recording medium 1004, amongst other things, is encoded with, i.e., stores, computer program code 1006, i.e., a set of executable instructions. Execution of instructions 1006 by hardware processor 1002 represents (at least in part) an EDA tool which implements a portion or all of the methods described herein in accordance with one or more embodiments (hereinafter, the noted processes and/or methods).

Processor 1002 is electrically coupled to computer-readable recording medium 1004 via a bus 1008. Processor 1002 is also electrically coupled to an I/O interface 1010 by bus 1008. A network interface 1012 is also electrically connected to processor 1002 via bus 1008. Network interface 1012 is connected to a network 1014, so that processor 1002 and computer-readable recording medium 1004 are capable of connecting to external elements via network 1014. Processor 1002 is configured to execute computer program code 1006 encoded in computer-readable recording medium 1004 in order to cause system 1000 to be usable for performing a portion or all of the noted processes and/or methods. In one or more embodiments, processor 1002 is a central processing unit (CPU), a multi-processor, a distributed processing system, an application specific integrated circuit (ASIC), and/or a suitable processing unit.

In one or more embodiments, computer-readable recording medium 1004 is an electronic, magnetic, optical, electromagnetic, infrared, and/or a semiconductor system (or apparatus or device). For example, computer-readable recording medium 1004 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1004 includes a compact disk-read only memory (CD-ROM), a compact disk-read/write (CD-R/W), and/or a digital video disc (DVD).

In one or more embodiments, recording medium 1004 stores computer program code 1006 configured to cause system 1000 (where such execution represents (at least in part) the EDA tool) to be usable for performing a portion or all of the noted processes and/or methods. In one or more embodiments, recording medium 1004 also stores information which facilitates performing a portion or all of the noted processes and/or methods. In one or more embodiments, recording medium 1004 stores library 1007 of standard cells including such standard cells as disclosed herein.

EDA system 1000 includes I/O interface 1010. I/O interface 1010 is coupled to external circuitry. In one or more embodiments, I/O interface 1010 includes a keyboard, keypad, mouse, trackball, trackpad, touchscreen, and/or cursor direction keys for communicating information and commands to processor 1002.

EDA system 1000 also includes network interface 1012 coupled to processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1000.

System 1000 is configured to receive information through I/O interface 1010. The information received through I/O interface 1010 includes one or more of instructions, data, design rules, libraries of standard cells, and/or other parameters for processing by processor 1002. The information is transferred to processor 1002 via bus 1008. EDA system 1000 is configured to receive information related to a UI through I/O interface 1010. The information is stored in computer-readable recording medium 1004 as user interface (UI) 1042.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1000. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

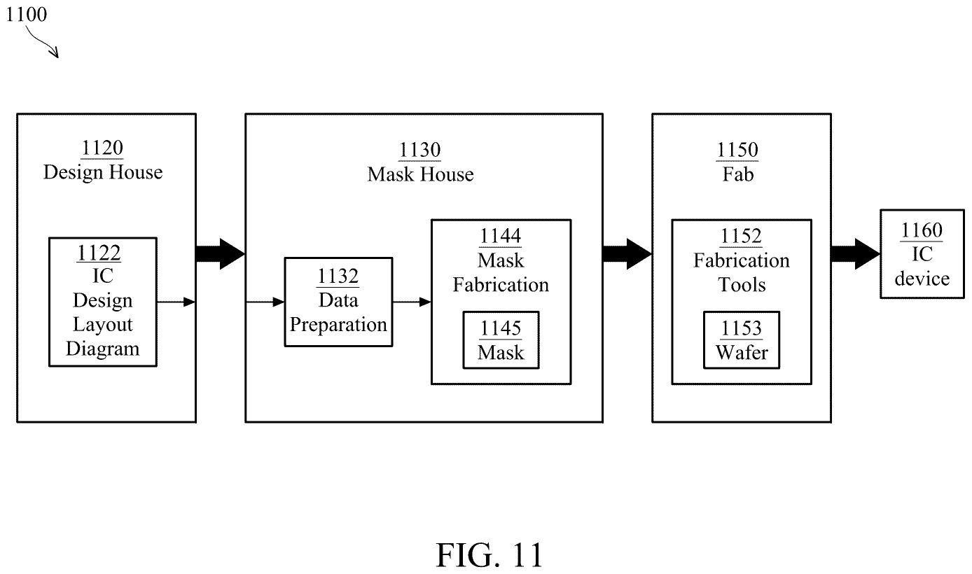

FIG. 11 is a block diagram of an integrated circuit (IC) manufacturing system 1100, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (“fab”) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout 1122. IC design layout 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout 1122. The design procedure includes one or more of logic design, physical design or place-and-route operation. IC design layout 1122 is presented in one or more data files having information of the geometrical patterns. For example, IC design layout 1122 can be expressed in a GDSII file format or DFII file format.

Mask house 1130 includes data preparation 1132 and mask fabrication 1144. Mask house 1130 uses IC design layout 1122 to manufacture one or more masks 1145 to be used for fabricating the various layers of IC device 1160 according to IC design layout 1122. Mask house 1130 performs mask data preparation 1132, where IC design layout 1122 is translated into a representative data file (“RDF”). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout 1122. In some embodiments, mask data preparation 1132 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 1122 to compensate for limitations during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1122.

It should be understood that the above description of mask data preparation 1132 has been simplified for the purposes of clarity. In some embodiments, data preparation 1132 includes additional features such as a logic operation (LOP) to modify the IC design layout 1122 according to manufacturing rules. Additionally, the processes applied to IC design layout 1122 during data preparation 1132 may be executed in a variety of different orders.

After mask data preparation 1132 and during mask fabrication 1144, a mask 1145 or a group of masks 1145 are fabricated based on the modified IC design layout 1122. In some embodiments, mask fabrication 1144 includes performing one or more lithographic exposures based on IC design layout 1122. In some embodiments, an electron-beam (e-beam) or a mechanism of multiple e-beams is used to form a pattern on a mask (photomask or reticle) 1145 based on the modified IC design layout 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC Fab 1150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some embodiments, an integrated circuit (IC) device comprises a substrate having a front side and a back side opposite the front side along a thickness direction of the substrate, an active region over the front side of the substrate, a first doped region of a first dopant type on the active region, a second doped region of a second dopant type on the active region, and a back side via extending from the back side, through the substrate, to the front side, and in into electrical contact with the first doped region. The second dopant type is different from the first dopant type. The first doped region and the second doped region configured as an anode and a cathode of a diode.

In some embodiments, an integrated circuit (IC) device comprises a substrate, first and second diodes, an input/output (I/O) pad, a first back side via and a second back side via. The substrate has a front side, and a back side opposite the front side along a thickness direction of the substrate. The first diode and the second diode are on the front side of the substrate. The I/O pad is electrically coupled to a cathode of the first diode and an anode of the second diode. The I/O pad is on the back side of the substrate. The first back side via extends from the back side, through the substrate, to the front side, and in electrical contact with one of an anode or the cathode of the first diode. The second back side via extends from the back side, through the substrate, to the front side, and in electrical contact with one of the anode or a cathode of the second diode.

In a method of manufacturing an integrated circuit (IC) device in accordance with some embodiments, dopants of a first dopant type are implanted into an active region over a front side of a substrate to form a first doped region, and dopants of a second dopant type different from the first dopant type are implanted into the active region to form a second doped region. A front side redistribution structure is deposited and patterned over the first doped region and the second doped region. The front side redistribution structure comprises a front side conductive structure electrically coupled to the second doped region. An opening is etched from a back side of the substrate to expose the first doped region, and a first conductive material is filled into the opening to obtain a back side via. A back side redistribution structure is deposited and patterned over the back side via. The back side redistribution structure comprises a first conductor electrically coupled to the back side via, and a second conductor electrically coupled to the front side conductive structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate having a front side, and a back side opposite the front side along a thickness direction of the substrate;
an active region over the front side of the substrate;
a first doped region of a first dopant type on the active region;
a second doped region of a second dopant type on the active region, the second dopant type different from the first dopant type, the first doped region and the second doped region configured as an anode and a cathode of a diode; and
a back side via extending from the back side, through the substrate, to the front side, and in electrical contact with the first doped region.

2. The IC device of claim 1, further comprising:
a first contact structure over and in electrical contact with the first doped region,
wherein the first contact structure and the back side via are in direct contact with corresponding opposite surfaces of the first doped region.

3. The IC device of claim 2, wherein
in a plan view along the thickness direction of the substrate, the first contact structure does not overlap the back side via.

4. The IC device of claim 2, wherein
in a plan view along the thickness direction of the substrate, the first contact structure overlaps a portion, not an entirety, of the back side via.

5. The IC device of claim 2, wherein
in a plan view along the thickness direction of the substrate, the first contact structure overlaps an entirety of the back side via.

6. The IC device of claim 2, further comprising: a plurality of back side vias, wherein the plurality of back side vias includes the back side via,
wherein each back side via of the plurality of back side vias extends from the back side, through the substrate, to the front side, and in electrical contact with the first doped region, and
the plurality of back side vias is arranged at an interval along the first contact structure.

7. The IC device of claim 1, further comprising:
a feed through via (FTV) extending, in the thickness direction, through the substrate, to the back side,
wherein the FTV is electrically coupled to the second doped region.

8. The IC device of claim 7, further comprising:
a first contact structure over and in electrical contact with the first doped region;
a second contact structure over and in electrical contact with the second doped region; and
a front side conductive structure on the front side and electrically coupling the second contact structure to the FTV.

9. The IC device of claim 8, further comprising:
an isolation structure next to the active region,
wherein the FTV is embedded in the isolation structure.

10. The IC device of claim 1, wherein
the IC device is free of a further back side via extending from the back side, through the substrate, to the front side, and in electrical contact with the second doped region.

11. An integrated circuit (IC) device, comprising:
a substrate having a front side, and a back side opposite the front side along a thickness direction of the substrate;
a first diode and a second diode on the front side of the substrate;
an input/output (I/O) pad electrically coupled to a cathode of the first diode and an anode of the second diode, wherein the I/O pad is on the back side of the substrate;
a first back side via extending from the back side, through the substrate, to the front side, and in electrical contact with one of an anode or the cathode of the first diode; and
a second back side via extending from the back side, through the substrate, to the front side, and in electrical contact with one of the anode or a cathode of the second diode.

12. The IC device of claim 11, further comprising:
at least one feed through via (FTV) extending, in the thickness direction, from the front side, through the substrate, to the back side, and having a greater length, in the thickness direction, than the first back side via and the second back side via,
wherein the at least one FTV comprises a first FTV electrically coupled
on the front side, to the cathode of the first diode or the anode of the second diode, and
on the back side, to the I/O pad.

13. The IC device of claim 12, wherein
the at least one FTV further comprises a second FTV electrically coupled
on the front side, to the anode of the first diode or the cathode of the second diode, and
on the back side, to a first power supply voltage, and
the first diode or the second diode is physically arranged between the first FTV and the second FTV.

14. The IC device of claim 13, wherein
the first back side via is in electrical contact with the anode of the first diode, and is electrically coupled, on the back side, to a second power supply voltage different from the first power supply voltage,
the second back side via is in electrical contact with the anode of the second diode, and is electrically coupled, on the back side, to the I/O pad,
the first FTV is electrically coupled to the cathode of the first diode on the front side, and
the second FTV is electrically coupled to the cathode of the second diode on the front side.

15. The IC device of claim 13, wherein
the first back side via is in electrical contact with the cathode of the first diode, and is electrically coupled, on the back side, to the I/O pad,
the second back side via is in electrical contact with the cathode of the second diode, and is electrically coupled, on the back side, to a second power supply voltage different from the first power supply voltage,
the first FTV is electrically coupled to the anode of the second diode on the front side, and
the second FTV is electrically coupled to the anode of the first diode on the front side.

16. The IC device of claim 11, further comprising:
first and second feed through vias (FTVs) each extending, in the thickness direction, from the front side, through the substrate, to the back side, and having a greater length, in the thickness direction, than the first back side via and the second back side via,
wherein
the first back side via is in electrical contact with the cathode of the first diode, and is electrically coupled, on the back side, to the I/O pad,
the second back side via is in electrical contact with the anode of the second diode, and is electrically coupled, on the back side, to the I/O pad,
the first FTV is electrically coupled
on the front side, to the anode of the first diode, and
on the back side, to a first power supply voltage, and
the second FTV is electrically coupled
on the front side, to the cathode of the second diode, and
on the back side, to a second power supply voltage different from the first power supply voltage.

17. The IC device of claim 11, further comprising:
a third back side via extending from the back side, through the substrate, to the front side, and in electrical contact with the anode of the first diode; and
a fourth back side via extending from the back side, through the substrate, to the front side, and in electrical contact with the cathode of the second diode,
wherein
the first back side via is in electrical contact with the cathode of the first diode, and is electrically coupled, on the back side, to the I/O pad,
the second back side via is in electrical contact with the anode of the second diode, and is electrically coupled, on the back side, to the I/O pad,
the third back side via is electrically coupled, on the back side, to a first power supply voltage, and
the fourth back side via is electrically coupled, on the back side, to a second power supply voltage different from the first power supply voltage.

18. A method, comprising:
implanting dopants of a first dopant type into an active region over a front side of a substrate to form a first doped region;
implanting dopants of a second dopant type different from the first dopant type into the active region to form a second doped region;
depositing and patterning a front side redistribution structure over the first doped region and the second doped region, the front side redistribution structure comprising a front side conductive structure electrically coupled to the second doped region;
from a back side of the substrate, etching an opening to expose the first doped region and filling a first conductive material into the opening to obtain a back side via; and
depositing and patterning a back side redistribution structure over the back side via, the back side redistribution structure comprising:
a first conductor electrically coupled to the back side via, and
a second conductor electrically coupled to the front side conductive structure.

19. The method of claim 18, further comprising:
before said depositing and patterning the front side redistribution structure, etching and depositing a second conductive material to form a feed through via (FTV) which extends, in a thickness direction of the substrate from the front side to the back side, along and beyond the first doped region and the second doped region; and
from the back side of the substrate, etching a further opening to expose the FTV and filling a conductive material into the further opening to obtain a conductive plug in electrical and physical contact with the FTV,
wherein
the front side conductive structure electrically couples the second doped region with the FTV, and
the back side redistribution structure comprises a back side conductive structure electrically coupling the conductive plug and the FTV to the second conductor.

20. The method of claim 18, further comprising:
implanting dopants of the first dopant type into a further active region over the front side of the substrate to form a further first doped region;
implanting dopants of the second dopant type into the further active region to form a further second doped region; and
from the back side of the substrate, etching a further opening to expose the further first doped region and filling a second conductive material into the further opening to obtain a further back side via,
wherein
the front side conductive structure electrically couples the second doped region to the further first doped region, and
the back side redistribution structure comprises a back side conductive structure electrically coupling the further back side via to the second conductor.
